(19) United States
(12) Patent Application Publication
(10) Pub. No.: US 2025/0112392 A1
(43) Pub. Date: Apr. 3, 2025

(54) SEMICONDUCTOR PACKAGE CARRIER, AND A CORRESPONDING SYSTEM AND METHOD OF USE

(71) Applicant: Intel Corporation, Santa Clara, CA (US)

(72) Inventors: Richard Canham, West Richland (WA); Ernesto Borboa Lizarraga, Zapopan (MX); Daniel Neumann, Tualatin, OR (US); Shelby Ferguson, El Dorado Hills, CA (US); Eric Buddrius, Hillsboro, OR (US); Hardikkumar Prajapati, Chandler, AZ (US); Kirk Wheeler, Chandler, AZ (US); Steven Klein, Chandler, AZ (US); Shaun Immeker, Wilton, CA (US); Jeffory L. Smalley, East Olympia, WA (US)

(73) Assignee: Intel Corporation, Santa Clara, CA (US)

(21) Appl. No.: 18/980,411

(22) Filed: Dec. 13, 2024

(51) Int. Cl. H01R 12/85

(52) U.S. Cl. CPC H01R 12/85

(57) ABSTRACT

A semiconductor package carrier used to support a semiconductor package (e.g., a semiconductor, a microprocessor, etc.) as the semiconductor package is moved from a shipping tray to a land grid array (LGA) socket during assembly of an electronic device. The semiconductor package carrier including a carrier body including a plurality of support structures arranged to support a portion of the semiconductor package. The semiconductor package carrier further including a locking structure moveable between a first position and a second position, wherein the first position allows the support structures to receive the semiconductor package and the second position secures the semiconductor package to the carrier body. In some embodiments, the semiconductor package carrier may also include a thermal interface material (TIM) breaker to facilitate removal of a heatsink from the semiconductor package. Other embodiments are described and claimed.

### BACKGROUND

A semiconductor package carrier may be used to support a semiconductor package as the semiconductor package is moved from a shipping tray to a land grid array (LGA) socket during assembly of an electronic device. The LGA socket may be physically mounted on a printed circuit board (PCB) of the electronic device. The LGA socket provides a physical and electrical interface between the semiconductor package encapsulating a semiconductor die and the PCB. The semiconductor package carrier may further ensure that the correct semiconductor package is installed and in the correct orientation.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates an exploded perspective view of a conventional Package-Heatsink Module (PHM) sub-assembly.

FIGS. 2A-2C illustrate a first embodiment of a semiconductor package carrier in accordance with one or more features of the present disclosure.

FIGS. 3A-3E illustrate a second embodiment of a semiconductor package carrier in accordance with one or more features of the present disclosure.

FIGS. 4A-4D illustrate a third embodiment of a semiconductor package carrier in accordance with one or more features of the present disclosure.

FIGS. 5A-5C illustrate a fourth embodiment of a semiconductor package carrier in accordance with one or more features of the present disclosure.

FIGS. 6A-6H illustrate a first embodiment of a thermal interface material (TIM) breaker in accordance with one or more features of the present disclosure.

FIGS. 7A-7E illustrate a second embodiment of a thermal interface material (TIM) breaker in accordance with one or more features of the present disclosure.

FIGS. 8A-8D illustrate a third embodiment of a thermal interface material (TIM) breaker in accordance with one or more features of the present disclosure.

FIGS. 9A-9C illustrate a fourth embodiment of a thermal interface material (TIM) breaker in accordance with one or more features of the present disclosure.

FIGS. 10A-10G illustrate a fifth embodiment of a thermal interface material (TIM) breaker in accordance with one or more features of the present disclosure.

FIG. 11 illustrates an embodiment of a process flow diagram for automating the carrier-to-package sub-assembly in accordance with one or more features of the present disclosure.

FIG. 12 illustrates an alternate embodiment of a process flow diagram for automating the carrier-to-package sub-assembly in accordance with one or more features of the present disclosure.

FIG. 13 illustrates an alternate embodiment of a process flow diagram for automating the carrier-to-package sub-assembly in accordance with one or more features of the present disclosure.

### DETAILED DESCRIPTION

Embodiments generally relate to a semiconductor package carrier used to safely move a semiconductor package from a shipping tray to, for example, a Land Grid Array (LGA) socket interface, which may be surface mounted to a circuit board such as, for example, a printed circuit board (PCB), such as a motherboard, of an electrical device. In use, the LGA socket interface provides a physical and electrical interface between the semiconductor package and the circuit board.

A Package-Heatsink Module (PHM) is a sub-assembly used to load a semiconductor package such as central processing units (CPUs), graphic processing units (GPUs), microprocessors, and/or other processor circuitry onto LGA sockets. One of the parts within a PHM sub-assembly is a semiconductor package carrier, which protects the semiconductor package during assembly. Functions of the semiconductor package carrier include safely moving the semiconductor package from a shipping tray to the LGA socket during assembly of the electronic device and ensuring the correct semiconductor package is installed in the correct orientation. Semiconductor package, LGA socket, and loading mechanism designs place design constraints on the semiconductor package carrier. Additionally, in some embodiments, it is desirable to have semiconductor package carriers pre-attached to the semiconductor package (carrier-to-package sub-assembly) in the shipping trays so that customers are relieved of the process of assembling the semiconductor packages and semiconductor package carriers and controlling carrier inventory. Though embodiments disclosed herein are described with a semiconductor package, other components to be coupled to a printed circuit board (PCB) or other substrate via a socket (e.g., an LGA socket) may also be coupled to the semiconductor package carrier embodiments disclosed herein.

The semiconductor package may encapsulate a semiconductor device, such as a semiconductor die or an integrated circuit (IC). Non-limiting examples of a semiconductor device includes semiconductor dies, ICs, memory ICs, chipsets, accelerators, controllers, transceivers, and so forth. A particular example of a semiconductor device comprises different processing units, collectively referred to as an “XPU,” where X stands for different letters depending on the context or specific function of the processing unit, which represents a shift towards more specialized, task-specific processors. Examples of an XPU include a central processing unit (CPU), graphics processing unit (GPU), data processing unit (DPU), vision processing unit (VPU), neural processing unit (NPU), infrastructure processing unit (IPU), tensor processing unit (TPU), and other processing units.

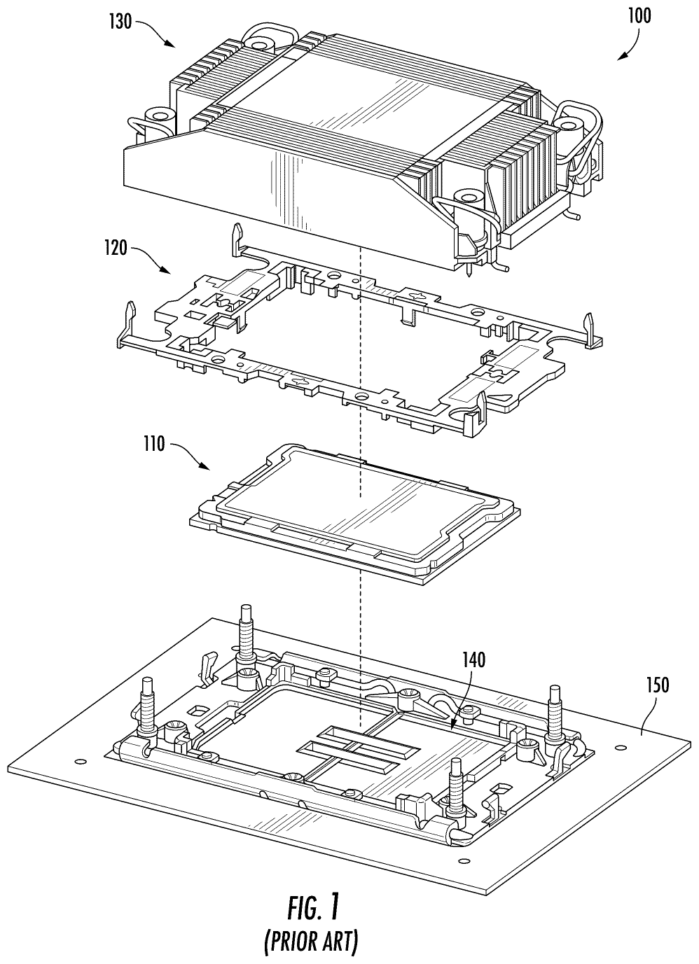

FIG. 1 is an exploded, perspective view of a conventional embodiment of a Package-Heatsink Module (PHM) sub-assembly 100. As illustrated, the PHM sub-assembly 100 includes a semiconductor package 110, a semiconductor package carrier 120, and a heatsink 130. Generally speaking, in use, customers receive a plurality of semiconductor packages, which are provided in a shipping tray (not shown). In addition, customers receive a plurality of semiconductor package carriers, which are provided in a shipping tray (not shown). Each semiconductor package carrier may be designed to receive a specific semiconductor package (e.g., each semiconductor package carrier is designed to receive a semiconductor package of a specific size and/or configuration). Currently, during assembling, a customer manually assembles the semiconductor package carrier 120 onto the semiconductor package 110. For example, the semiconductor package carrier 120 may be mechanically coupled to the semiconductor package 110 by positionally the semiconductor package carrier 120 vertically above a top surface of the semiconductor package 110 and vertically moving the semiconductor package carrier 120 downwards onto the semiconductor package 110 until clips on the semiconductor package carrier 120 engage a bottom surface of the semiconductor package 110. That is, with the semiconductor package 110 remaining in the shipping tray, a semiconductor package carrier 120 is typically assembly from the top of the semiconductor package 110 until projections or tabs formed on the semiconductor package carrier 120 snap onto the bottom surface of the semiconductor package 110. Thus arranged, the bottom surface of the semiconductor package 110 remains accessible to contact connector pins in an LGA socket 140. In addition, the semiconductor package carrier 120 includes an opening in the top surface thereof so that the top surface of the semiconductor package 110 is accessible. Thereafter, the semiconductor package 110 may be coupled to the heatsink 130 via a thermal interface material. Finally, the PHM sub-assembly 100 may be coupled to the LGA socket 140, which may be surface mounted to a circuit board 150. Generally speaking, each semiconductor package 110 is manually coupled to one of the semiconductor package carriers 120. As a result, customers are generally responsible for ordering and managing the inventory of semiconductor packages 110 and corresponding semiconductor package carriers 120, which has led to incorrect inventory, long lead times, and customer complaints. In addition, customers are responsible for assembling the semiconductor package carrier 120 onto the semiconductor package 110, which has caused reduced throughput, damage to the semiconductor package 110, and downtime for incorrect inventory.

It would be beneficial for semiconductor packages to arrive at customer's sites pre-attached with a semiconductor package carrier to relieve customers of the carrier-to-package sub-assembly process and associated inventory control. In addition, and/or alternatively, it would be beneficial to provide an improved semiconductor package carrier design that facilitates automated assembly of the carrier-to-package sub-assembly process.

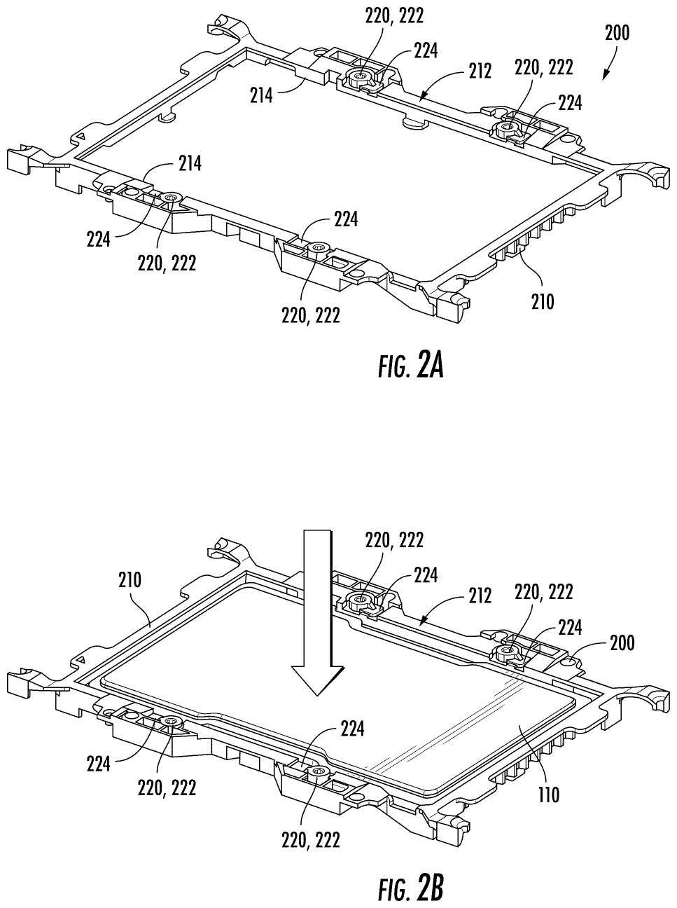

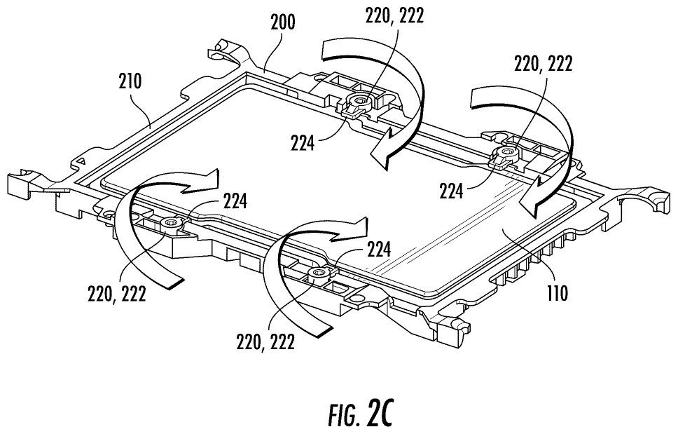

FIGS. 2A-2C illustrate a first embodiment of a semiconductor package carrier 200 in accordance with one or more features of the present disclosure. FIG. 2A illustrates the semiconductor package carrier 200 in a first or opened position. FIG. 2B illustrates a semiconductor package positioned within the semiconductor package carrier 200. FIG. 2C illustrates the semiconductor package carrier 200 in a second or closed position to secure the semiconductor package within the semiconductor package carrier 200.

As illustrated, in some embodiments, the semiconductor package carrier 200 includes a carrier body 210 including a plurality of support structures 212 to receive and support a semiconductor package such as, for example, semiconductor package 110, at least partially therein. As illustrated, the carrier body 210 may include an opening formed therein to enable the semiconductor package 110 to be accessible therethrough for contacting the connector pins of an LGA socket. As such, in some embodiments, the semiconductor package carrier 200 may be used in place of the semiconductor package carrier 120 in the PHM sub-assembly 100.

That is, in some embodiments, during use, the carrier body 210 may receive and support the semiconductor package 110 therein. For example, the plurality of support structures 212 can be arranged as any suitable structure now known or hereafter developed to receive and support the semiconductor package 110 within the semiconductor package carrier 200 such as, for example, a shelf, a ledge, clips, projections and recesses, etc. such that the semiconductor package 110 is held within the semiconductor package carrier 200 when, for example, the semiconductor package 110 is vertically inserted within the carrier body 210 as shown in FIG. 2B (e.g., the semiconductor package 110 can be vertically inserted into the semiconductor package carrier 200 but cannot pass completely therethrough).

In addition, in accordance with one or more features of the present disclosure, the carrier body 210 may include a plurality of locking structures 220 positioned about a periphery 214 of the support structures 212 and/or openings. In use, each of the locking structures 220 may be moveable between a first or opened position (FIGS. 2A and 2B) and a second or closed position (FIG. 2C). In addition, as illustrated, each of the locking structures 220 may be arranged as a clip 222 rotatably coupled to the carrier body 210. Each of the plurality of clips 222 including a support tab 224 to secure the semiconductor package 110 when in the second or closed position. Thus, in use, with the locking structure 220 (e.g., plurality of clips 222) in the first or opened position, the semiconductor package 110 can be inserted into the carrier body 210. Thereafter, the locking structure 220 (e.g., plurality of clips 222) may be rotated from the first or opened position to the second or closed position such that the support tabs 224 extend partially perpendicular to the periphery 214 and across at least a portion of the semiconductor package 110 as shown in FIG. 2C. Thus arranged, the support tabs 224 hold the semiconductor package 110 within the semiconductor package carrier 200 thereby preventing the semiconductor package 110 from disengaging from the semiconductor package carrier 200 (e.g., with the semiconductor package 110 inserted into the semiconductor package carrier 200, rotation of the plurality of clips 222 from the first or opened position to the second or closed position positions the support tabs 224 over the semiconductor package 110 thereby preventing the semiconductor package 110 from falling out of the semiconductor package carrier 200). In some embodiments, as illustrated, the semiconductor package 110 may be placed down into the semiconductor package carrier 200. The clips 222 may be rotated 90-degrees to position the support tabs 224 over the semiconductor package 110 to secure a top side of the semiconductor package 110 thereby cradling the semiconductor package 110 within the semiconductor package carrier 200.

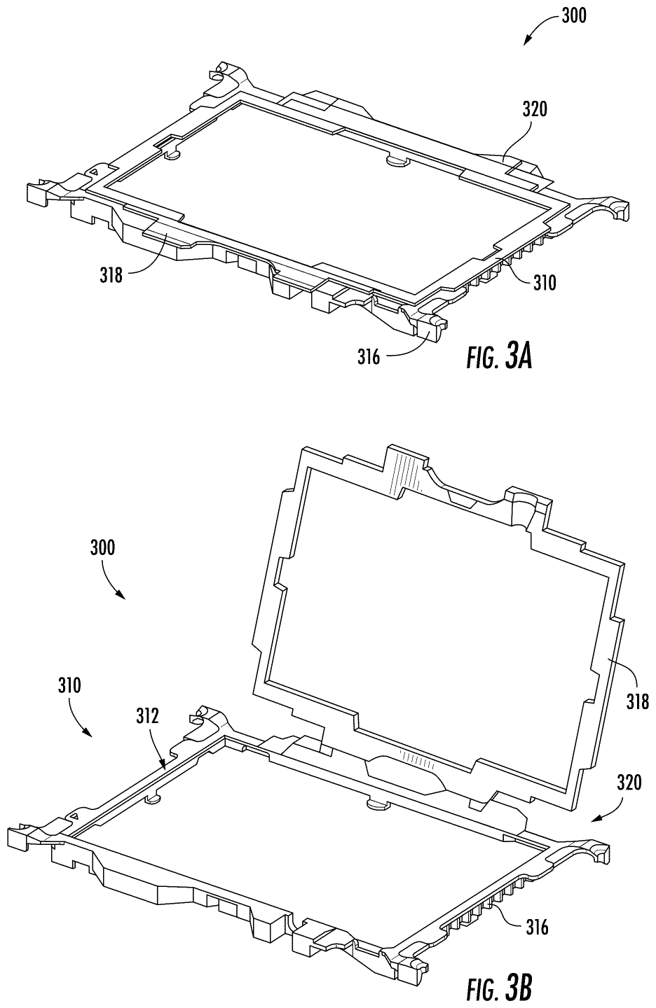

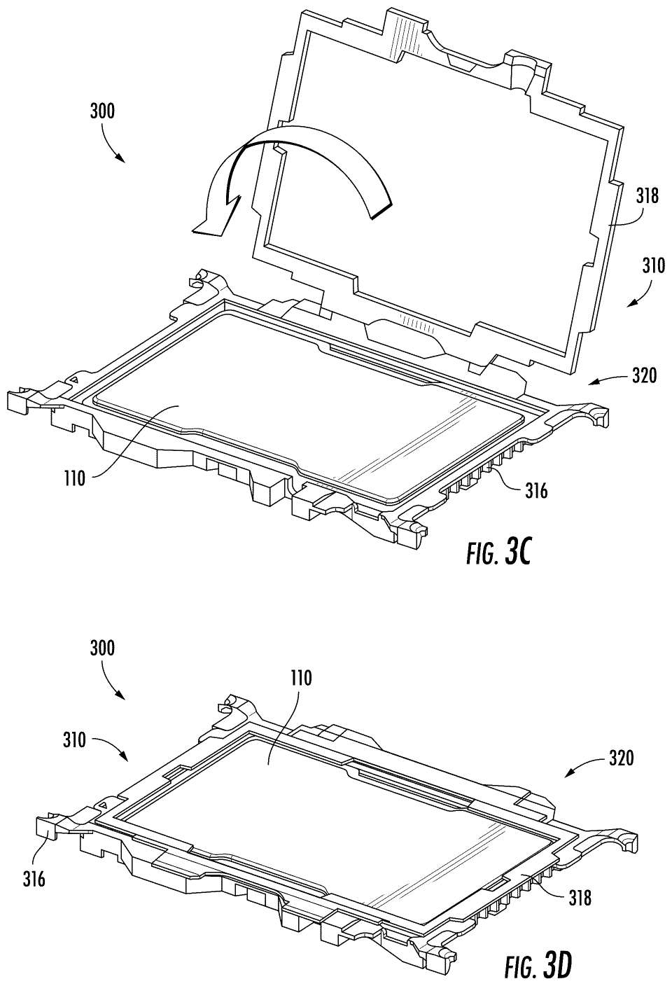

FIGS. 3A-3E illustrate a second embodiment of a semiconductor package carrier 300 in accordance with one or more features of the present disclosure. FIG. 3A illustrates the semiconductor package carrier 300 in a second or closed position. FIG. 3B illustrates the semiconductor package carrier 300 in a first or opened position. FIG. 3C illustrates a semiconductor package positioned within the semiconductor package carrier 300. FIG. 3D illustrates the semiconductor package carrier 300 in the second or closed position to secure the semiconductor package within the semiconductor package carrier 300. FIG. 3E illustrates a detailed view of an embodiment for securing the semiconductor package carrier 300 in the second or closed position.

As illustrated, the semiconductor package carrier 300 includes a carrier body 310 including a plurality of support structures 312 to receive and support a semiconductor package such as, for example, semiconductor package 110, at least partially therein. As illustrated, the carrier body 310 may include an opening formed therein to enable the top and bottom surfaces of the semiconductor package 110 to be accessible therethrough for contacting the heatsink and connector pins of an LGA socket, respectively. As such, in some embodiments, the semiconductor package carrier 300 may be used in place of the semiconductor package carrier 120 in the PHM sub-assembly 100.

That is, in some embodiments, during use, the carrier body 310 may receive and support the semiconductor package 110 therein. For example, the plurality of support structure 312 can be arranged as any suitable structure now known or hereafter developed to receive and support the semiconductor package 110 within the semiconductor package carrier 300 such as, for example, a shelf, a ledge, clips, projections and recesses, etc. such that the semiconductor package 110 is held within the semiconductor package carrier 300 when, for example, the semiconductor package 110 is vertically inserted within the carrier body 310 (e.g., the semiconductor package 110 can be vertically inserted into the semiconductor package carrier 300 but cannot pass completely therethrough).

In addition, in accordance with one or more features of the present disclosure, the carrier body 310 includes a first body portion 316 and a second body portion 318 pivotably or hingeably coupled to the first body portion 316 along a side thereof. Thus arranged, the semiconductor package carrier 300 may be described as having a locking structure 320, which comprises of pivotably or hingeably moving the second body portion 318 relative to the first body portion 316 after the semiconductor package 110 is inserted into the first body portion 316 to secure a position of the semiconductor package 110 within the semiconductor package carrier 300.

That is, with reference to FIGS. 3A and 3B, the second body portion 318 may be moved or pivoted relative to the first body portion 316 from the second or closed position to the first or opened position, or may be provided in the first or opened position. Thereafter, with reference to FIG. 3C, the semiconductor package 110 may be vertically inserted within the first body portion 316 of the carrier body 310. Next, with reference to FIG. 3D, the second body portion 318 may be pivotably moved from the first or opened position to the second or closed position. In the second or closed position, with reference to FIG. 3E, the first and second body portions 316, 318 may include interconnecting projections 330 and recesses 332 to couple the second body portion 318 to the first body portion 316 to encapsulate the semiconductor package 110 between the first and second body portions 316, 318 to secure the position of the semiconductor package 110 within the semiconductor package carrier 300.

In some embodiments, as illustrated, second body portion 318 may be pivotably (e.g., hingeably) moved relative to the first body portion 316. Thus arranged, with the carrier body 310 in the first or opened position, the semiconductor package 110 may be inserted or placed down into the first body portion 316 of the carrier body 310. Next, the second body portion 318 may be pivoted (e.g., rotated) so that the second body portion 318 engages the first body portion 316 and encases the semiconductor package 110 within the carrier body 310 between the first and second body portions 316, 318.

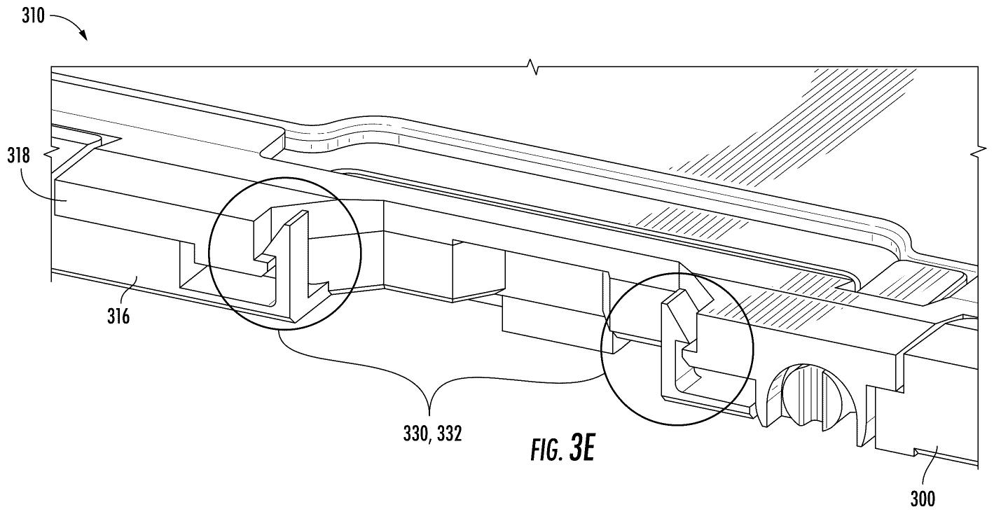

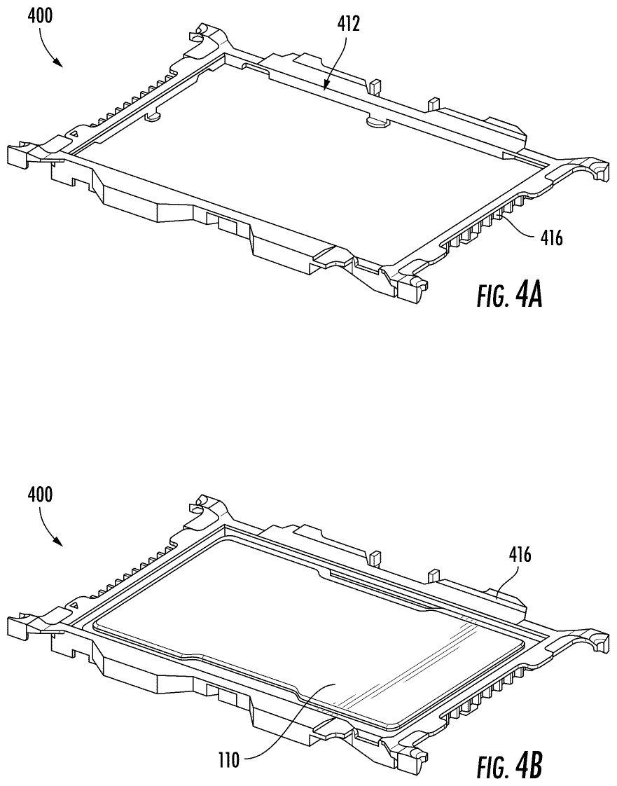

FIGS. 4A-4D illustrate a third embodiment of a semiconductor package carrier 400 in accordance with one or more features of the present disclosure. FIG. 4A illustrates the semiconductor package carrier 400 in a first or opened position. FIG. 4B illustrates a semiconductor package positioned within the semiconductor package carrier 400. FIG. 4C illustrates an exploded, perspective view of the semiconductor package carrier 400. FIG. 4D illustrates the semiconductor package carrier 400 in a second or closed position to secure the semiconductor package within the semiconductor package carrier 400.

As illustrated, the semiconductor package carrier 400 includes a carrier body 410 including a first body portion 416 and a second body portion 418, at least the first body portion 416 including a plurality of support structures 412 to receive and support a semiconductor package such as, for example, semiconductor package 110, at least partially therein, although this is but one configuration and both the first and second body portions 416, 418 may include support structures 412. As illustrated, the carrier body 410 may include an opening formed therein to enable the top and bottom surfaces of the semiconductor package 110 to be accessible therethrough for contacting the heatsink and connector pins of an LGA socket, respectively. As such, in some embodiments, the semiconductor package carrier 400 may be used in place of the semiconductor package carrier 120 in the PHM sub-assembly 100.

That is, with reference to FIG. 4A, during use, the carrier body 410 may receive and support the semiconductor package 110 therein. For example, the first body portion 416 may include a plurality of support structures 412 to receive and support the semiconductor package 110 therein. For example, the plurality of support structures 412 can be arranged as any suitable structure now known or hereafter developed to support the semiconductor package 110 within the semiconductor package carrier 400 such as, for example, a shelf, a ledge, clips, projections and recesses, etc. such that the semiconductor package 110 is held within the semiconductor package carrier 400 when, for example, the semiconductor package 110 is vertically inserted within the first body portion 416 (e.g., the semiconductor package 110 can be vertically inserted into the semiconductor package carrier 300 but cannot pass completely therethrough). Thereafter, with the semiconductor package 110 inserted within the first body portion 416 (FIG. 4B), the second body portion 418 may be coupled to the first body portion 416 (FIGS. 4C and 4D). Thus arranged, the semiconductor package carrier 400 may be described as having a locking structure, which comprises of coupling the second body portion 418 to the first body portion 416 after the semiconductor package 110 is inserted into the first body portion 416 to secure the position of the semiconductor package 110 within the semiconductor package carrier 400.

That is, with reference to FIGS. 4A and 4B, with the second body portion 418

disconnected from the first body portion 416, the semiconductor package 110 may be vertically inserted within the first body portion 416. Next, with reference to FIGS. 4C and 4D, the second body portion 418 may be coupled to first body portion 416. In some embodiments, the first and second body portions 416, 418 may include interconnecting projections and recesses to couple the second body portion 418 to the first body portion 416 to encase the semiconductor package 110 between the first and second body portions 416, 418.

In some embodiments, as illustrated, with the semiconductor package carrier 400 in the first or opened position (e.g., with the second body portion 418 decoupled from the first body portion 416), the semiconductor package 110 may be inserted or placed down into the first body portion 416. Next, the second body portion 418 may be coupled to the first body portion 416 thereby encasing the semiconductor package 110 within the carrier body 410 between the first and second body portions 416, 418.

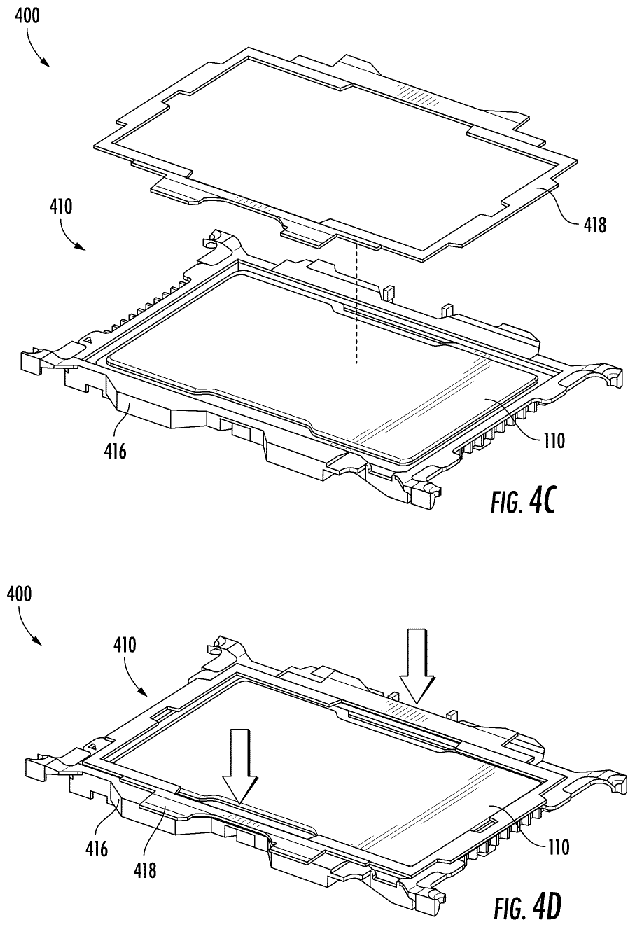

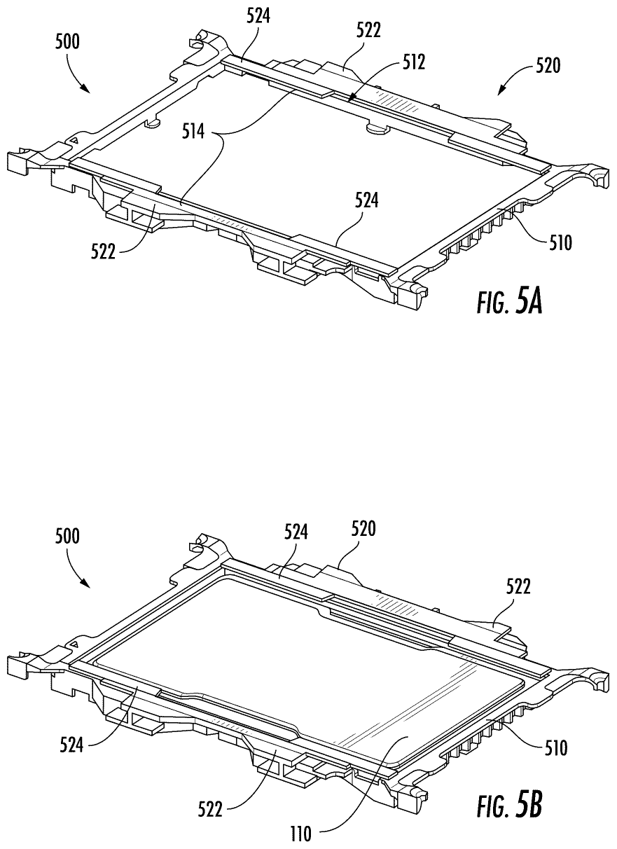

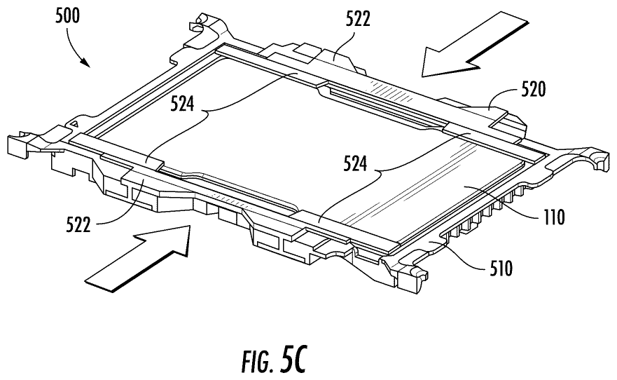

FIGS. 5A-5C illustrate a fourth embodiment of a semiconductor package carrier 500 in accordance with one or more features of the present disclosure. FIG. 5A illustrates the semiconductor package carrier 500 in a first or opened position. FIG. 5B illustrates a semiconductor package positioned within the semiconductor package carrier 500. FIG. 5C illustrates the semiconductor package carrier 500 in a second or closed position to secure the semiconductor package within the semiconductor package carrier 500.

As illustrated, the semiconductor package carrier 500 includes a carrier body 510 including a plurality of support structures 512 to receive and support a semiconductor package such as, for example, semiconductor package 110, at least partially therein. As illustrated, the carrier body 510 may include an opening formed therein to enable the semiconductor package 110 to be accessible therethrough for contacting the connector pins of an LGA socket, respectively. As such, in some embodiments, the semiconductor package carrier 500 may be used in place of the semiconductor package carrier 120 in the PHM sub-assembly 100.

That is, in some embodiments, during use, the carrier body 510 may receive and support the semiconductor package 110 therein. For example, the plurality of support structures 512 can be arranged as any suitable structure to receive and support the semiconductor package 110 within the semiconductor package carrier 500 such as, for example, a shelf, a ledge, clips, projections and recesses, etc. such that the semiconductor package 110 is held with the semiconductor package carrier 500 when, for example, the semiconductor package 110 is vertically inserted within the carrier body 510 (e.g., the semiconductor package 110 can be vertically inserted into the semiconductor package carrier 500 but cannot pass completely therethrough).

In addition, in accordance with one or more features of the present disclosure, the carrier body 510 includes a locking structure 520 positioned about a periphery 514 of the support structure 512 and/or opening. In use, the locking structures 520 may be moveable between a first or opened position (FIGS. 5A and 5B) and a second or closed position (FIG. 5C). In some embodiments, as illustrated, the locking structure 520 may be arranged as, or operatively include a lever or tab 522 moveably coupled to the carrier body 510. For example, the semiconductor package carrier 500 may include first and second levers or tabs 522 positioned on either side thereof. In some embodiments, each of the levers or tabs 522 include one or more support tabs 524 to secure the semiconductor package 110 within the carrier body 510 when in the second or closed position. In some embodiments, each of the plurality of levers or tabs 522 may be positioned along first and second surfaces of the carrier body 510. Thus arranged, in use, with the semiconductor package 110 received within the carrier body 510, the levers or tabs 522 may be moved to the second or closed position (e.g., moved, pressed, or slide towards each other and/or a central longitudinal axis of the semiconductor package carrier 500).

Thus, in use, with the locking structure 520 (e.g., plurality of levers or tabs 522) in the first or opened position, the semiconductor package 110 can be inserted into the carrier body 510. Thereafter, the locking structure 520 (e.g., plurality of lever or tabs 522) may be moved from the first or opened position to the second or closed position such that the support tabs 524 extend partially perpendicular to the periphery 514 and across at least a portion of the semiconductor package 110. Thus arranged, the support tabs 524 hold the semiconductor package 110 within the semiconductor package carrier 500 thereby preventing the semiconductor package 110 from disengaging from the semiconductor package carrier 500 (e.g., with the semiconductor package 110 inserted into the semiconductor package carrier 500, movement (e.g., sliding of the plurality of levers or tabs 522) from the first or opened position to the second or closed position positions the support tabs 524 above the semiconductor package 110 thereby preventing the semiconductor package 110 from falling out of the semiconductor package carrier 500). In some embodiments, as illustrated, the semiconductor package 110 may be inserted or placed down into the carrier body 510 of the semiconductor package carrier 500. The lever or tabs 522 may be slide or pressed towards each other (e.g., towards a longitudinal axis of the semiconductor package carrier 500) to position the support tabs 524 over the semiconductor package 110 to secure a top side of the semiconductor package 110 thereby cradling the semiconductor package 110 within the semiconductor package carrier 500.

In accordance with one or more features of the present disclosure, the semiconductor package carriers 200, 300, 400, 500 may also include a thermal interface material (“TIM”) breaker. That is, as previously mentioned, during the Package-Heatsink Module (PHM) sub-assembly process, upon coupling the semiconductor package carrier to the semiconductor package, a thermal interface material may be applied to a top surface of the semiconductor package for purposes of adhering a heatsink such as, for example, heatsink 130, to the semiconductor package (e.g., in use, the thermal interface material turns into a paste with heat and spreads across the top surface of the semiconductor package, the thermal interface material eventually hardens adhering the heatsink to the semiconductor package). From time to time, the semiconductor package may need to be disconnected from the heatsink. Thus, in accordance with one or more features of the present disclosure, the semiconductor package carriers may also include a TIM breaker to facilitate removing the heatsink from the semiconductor package (e.g., TIM breaker facilitates breaking, prying, ejecting, etc. the heatsink from the semiconductor package). That is, the TIM breaker facilitates disengagement of the heatsink from the semiconductor package. In use, incorporation of a TIM breaker prevents, or at least discourages, the use of an external tool such as, for example, a screwdriver, being used to pry the heatsink from the semiconductor package, thus reducing the potential for damaging the semiconductor package caused by removing the heatsink.

With conventional semiconductor package carriers being coupled to semiconductor packages from the top side of the semiconductor package, conventional TIM breaker placement was guaranteed given that the TIM breaker was already registered into the semiconductor package carrier. However, in connection with one or more features of the present disclosure, with the advent of automation and the placing of the semiconductor package into the semiconductor carrier package along the bottom side of the semiconductor package, TIM breakers now need to reside on the top surface of the semiconductor package carrier while avoiding interfering with inserting the semiconductor package into the semiconductor package carrier. As such, similar to one or more features of the locking structures, the TIM breaker needs to move from a first or opened position, wherein the TIM breaker enables the semiconductor package to be inserted into the semiconductor package carrier, to a second or closed position, wherein the TIM breaker can eventually reside between the semiconductor package and the heatsink.

While the present disclosure will illustrate and describe numerous embodiments of a TIM breaker in accordance with one embodiment of a semiconductor package carrier, it should be appreciated that the TIM breakers described herein can be used separate and apart from any specific semiconductor package carrier. As such, it should be appreciated that the various embodiments of TIM breakers can be used in connection with any semiconductor package carrier described herein and/or any suitable semiconductor package carrier now known or hereafter developed. Thus, the TIM breakers are not to be limited to any particular semiconductor package carrier unless explicitly claimed.

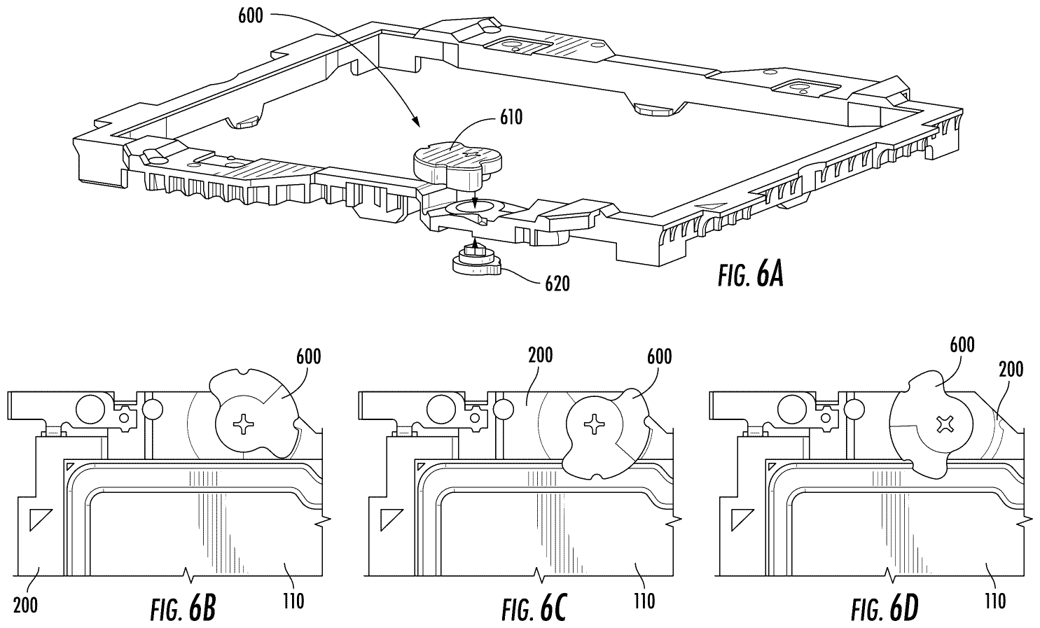

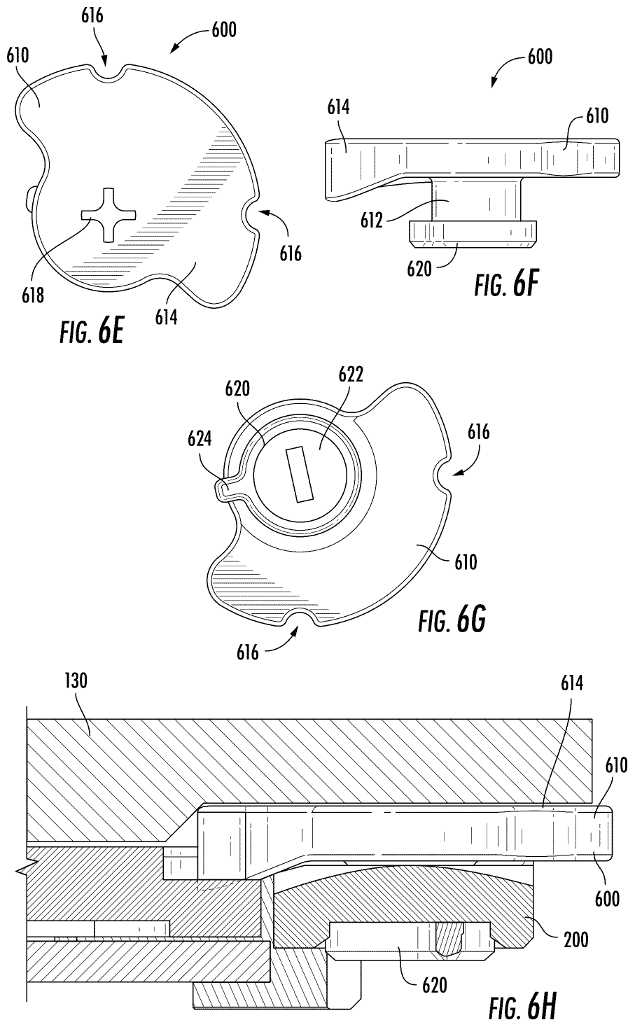

FIGS. 6A-6H illustrate a first embodiment of a TIM breaker 600 in accordance with one or more features of the present disclosure. FIG. 6A illustrates an exploded perspective view of the TIM breaker 600 being coupled to a semiconductor package carrier such as, for example, semiconductor package carrier 200, 300, 400, 500 (illustrated as semiconductor package carrier 200). FIG. 6B illustrates the TIM breaker 600 in a first or opened position. FIG. 6C illustrates the TIM breaker 600 in a second or closed position. FIG. 6D illustrates the TIM breaker 600 in a third position. FIG. 6E illustrates a top view of the TIM breaker 600. FIG. 6F illustrates a side view of the TIM breaker 600. FIG. 6G illustrates a bottom view of the TIM breaker 600. FIG. 6H illustrates a side, cross-sectional view of the TIM breaker 600 inserted into a semiconductor package carrier.

As illustrated, the TIM breaker 600 may be arranged as a twisting or rotatable structure, cam, or clip. In use, one or more TIM breakers 600 may be used in place of, or in addition to, one or more locking structures. As illustrated, in some embodiments, the TIM breaker 600 (e.g., rotatable clip) may include a first body portion 610 and a second body portion 620. In use, the first body portion 610 may include a shaft 612 such as, for example, a downwardly extending shaft, to extend through an opening formed in the carrier body 210 of the semiconductor package carrier 200. The second body portion 620 engaging the shaft 612 of the first body portion 610 after the shaft 612 has been inserted through the opening formed in the carrier body 210 of the semiconductor package carrier 200, although this is but one configuration for coupling the TIM breaker to the semiconductor package carrier. For example, alternatively, the TIM breaker may comprise a single, monolithic piece or component that can be coupled to the semiconductor package carrier such as, for example, via a slot formed in the carrier body of the semiconductor package carrier.

As illustrated, in some embodiments, the first body portion 610 may be arranged as a wedge having an inclined top surface 614. The TIM breaker 600 (e.g., rotatable clip) may be positioned about the periphery 214 of the support structure 212 and/or opening formed in the semiconductor package carrier 200. Referring to FIGS. 6B-6D, in use, the TIM breaker 600 (e.g., rotatable clip) may be moved (e.g., rotated) through a range of positions including, for example, a first or opened position (FIG. 6B), a second or closed position (FIG. 6C), and a third position (FIG. 6D). In the first or opened position, the TIM breaker 600 (e.g., rotatable clip) enables the semiconductor package 110 to be at least partially received within the carrier body 210 of the semiconductor package carrier 200. Thereafter, with the semiconductor package 110 inserted into the semiconductor package carrier 200, movement of the TIM breaker 600 (e.g., rotatable clip) from the first or opened position to the second or closed position causes a portion of the TIM breaker 600 (e.g., rotatable clip) to be positioned above the top surface of the semiconductor package 110, and eventually between the top surface of the semiconductor package 110 and the bottom surface of the heatsink 130. Rotation of the TIM breaker 600 (e.g., rotatable clip) to the second or closed position causes at least a portion of the first body portion 610 to extend partially perpendicular to the periphery 214 and across at least a portion of the semiconductor package 110 to hold the semiconductor package 110 within the semiconductor package carrier 200 thereby preventing the semiconductor package 110 from disengaging from the semiconductor package carrier 200. Thus arranged, the TIM breaker 600 (e.g., rotatable clip) facilitates securement of the semiconductor package 110 to the semiconductor package carrier 200 similar to one or more of the locking structures previously described. Thus arranged, the TIM breaker 600 acts as a locking or retention clip. Subsequently, if the heatsink 130 needs to be decoupled from the semiconductor package 110, rotation of the TIM breaker 600 (e.g., rotatable clip) to the third position (FIG. 6D) causes the inclined top surface 614 to contact or wedge between the top surface of the semiconductor package 110 and the bottom surface of the heatsink 130 to facilitate disengagement of the heatsink 130 from the semiconductor package 110.

With reference to FIGS. 6E-6G, in some embodiments, the TIM breaker 600 may include one or more detents 616 to indicate relative positions. In addition, and/or alternatively, the TIM breaker 600 may include a tool interface 618 for receiving an external tool to assist with rotating the TIM breaker 600. For example, a slot for receiving a screwdriver. In addition, and/or alternatively, the TIM breaker 600 may include a tool interface 622 on the bottom surface thereof to allow manually breaking/rotating the TIM breaker 600. In addition, and/or alternatively, the TIM breaker 600 may include a blocking feature 624 to prevent over-rotation of the TIM breaker 600 to prevent, or at least minimize, damaging the semiconductor package carrier 200.

In one embodiment of use, the semiconductor package carriers 200 may be received with the TIM breaker 600 (e.g., rotatable clip) in the first or opened position. Alternatively, the TIM breaker 600 (e.g., rotatable clip) may be rotated to the first or opened position. Next, a semiconductor package 110 may be inserted into the semiconductor package carrier 200. In preferred embodiments, the semiconductor package 110 may be inserted into the semiconductor package carrier 200 within the manufacturer's facilitates using automated equipment. With the semiconductor package 110 properly positioned within the semiconductor package carrier 200, each of the locking structures and/or TIM breakers 600 may be moved (e.g., rotated) to the second or closed positions to secure the position of the semiconductor package 110 within the semiconductor package carrier 200. This may be done either manually or via automated equipment. Next, the shipping trays including the carrier-to-package sub-assembly may be shipped to customers where, in some embodiments, the customer may apply the thermal interface material to adhere the heatsink 130 to the semiconductor package 110. Thereafter, as needed, if the customer needs to remove the heatsink 130 from the semiconductor package 110, the TIM breaker 600 can be further rotated using, for example, a screwdriver, to move the TIM breaker 600 to the third position where the inclined top surface 614 of the TIM breaker 600 causes the heatsink 130 to separate from the semiconductor package 110.

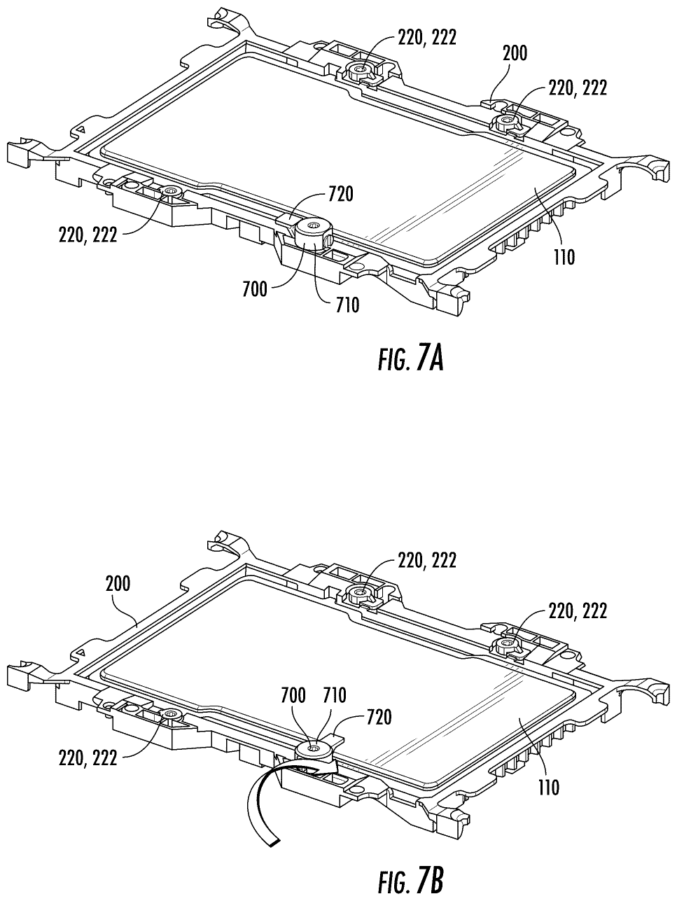

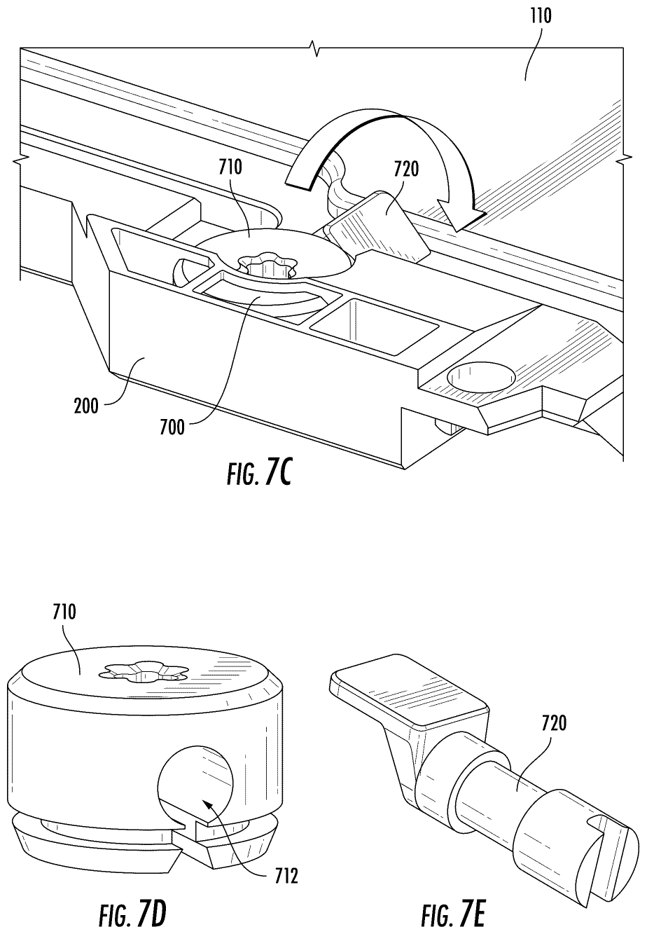

FIGS. 7A-7E illustrate a second embodiment of a TIM breaker 700 in accordance with one or more features of the present disclosure. FIG. 7A illustrates the TIM breaker 700 coupled to a semiconductor package carrier such as, for example, semiconductor package carrier 200, 300, 400, 500 (illustrated as semiconductor package carrier 200). The TIM breaker 700 illustrated in a first or opened position. FIG. 7B illustrates the TIM breaker 700 in a second or closed position. FIG. 7C illustrates the TIM breaker 700 manipulated to a third position or configuration. FIG. 7D illustrates a perspective view of a body or collet 710 of the TIM breaker 700. FIG. 7E illustrates a perspective view of a rotatable support tab 720 of the TIM breaker 700. As illustrated, the TIM breaker 700 may be arranged as a collet including a rotatable support tab. In use, one or more TIM breakers 700 may be used in place of, or in addition to, one or more the locking structures.

As illustrated, in some embodiments, the TIM breaker 700 includes a body or collet 710 and a support tab 720 rotatably coupled to the body or collet 710. For example, as illustrated, the body or collet 710 may include an opening 712 formed therein for receiving a portion of the support tab 720. The body or collet 710 may be arranged as a cylindrical body. In use, the TIM breaker 700 may be positioned about a periphery 214 of the support structure 212 and/or opening formed in the semiconductor package carrier 200. Referring to FIGS. 7A and 7B, in use, the body or collet 710 can be rotated about a first axis extending substantially perpendicular to a top surface of the semiconductor package carrier 200. Thus arranged, the body or collet 710 may be moved (e.g., rotated) through a range of positions including, for example, a first or opened position (FIG. 7A) and a second or closed position (FIG. 7B). In the first or opened position, the body or collet 710 is positioned so that the support tab 720 enables the semiconductor package 110 to be at least partially received within the carrier body 210 formed in the semiconductor package carrier 200 (e.g., the support tab 720 is rotated out of the way to enable the semiconductor package 110 to be inserted into the semiconductor package carrier 200). Thereafter, with the semiconductor package 110 inserted into the semiconductor package carrier 200, movement (e.g., rotation) of the body or collet 710 from the first or opened position to the second or closed position causes a portion of the support tab 720 to be positioned above the top surface of the semiconductor package 110, and eventually between the top surface of the semiconductor package 110 and the bottom surface of the heatsink 130. Rotation of the body or collet 710 to the second or closed position causes at least a portion of the support tab 720 to extend partially perpendicular to the periphery 214 and across at least a portion of the semiconductor package 110 to hold the semiconductor package 110 within the semiconductor package carrier 200 thereby preventing the semiconductor package 110 from disengaging from the semiconductor package carrier 200. As such, the support tab 720 facilitates securement of the semiconductor package 110 to the semiconductor package carrier 200 similar to one or more of the locking structures previously described. Thus arranged, the TIM breaker 700 acts as a locking or retention clip. Subsequently, with reference to FIG. 7C, if the heatsink 130 needs to be decoupled from the semiconductor package 110, the support tab 720 may be rotated about a second axis relative to the body or collet 710, the second axis being substantially perpendicular to the first axis. Rotation of the support tab 720 causes the end of the support tab 720 to contact and/or pry the heatsink 130 from the semiconductor package 110 to facilitate disengagement of the heatsink 130 from the semiconductor package 110.

As such, in use, TIM breaker 700 allows for two degrees of rotation. The body or collet 710 can be rotated between a first or opened position and a second or closed position to facilitate insertion and/or securement of the semiconductor package 110 within the semiconductor package carrier 200. Thereafter, if needed, the support tab 720 can be rotated relative to the body or collet 710 via, for example, an external tool such as a screwdriver, to separate the heatsink 130 from the semiconductor package 110.

In one embodiment of use, the semiconductor package carriers may be received with the TIM breaker 700 (e.g., body or collet 710 and support tab 720) in the first or opened position. Alternatively, the TIM breaker 700 may be moved to the first or opened position. Next, a semiconductor package 110 may be inserted into the semiconductor package carrier 200. In preferred embodiments, the semiconductor package 110 may be inserted into the semiconductor package carrier 200 within the manufacturer's facilitates using automated equipment. With the semiconductor package 110 properly positioned within the semiconductor package carrier 200, each of the locking structures and/or TIM breakers 700 (e.g., body or collet 710 and support tab 720) may be moved (e.g., rotated) to the second or closed position so that the support tab 720 partially resides above the top surface of the semiconductor package 110 to secure the position of the semiconductor package 110 within the semiconductor package carrier 200. This may be done either manually or via automated equipment. Next, the shipping trays including the carrier-to-package sub-assembly may be shipped to customers where, in some embodiments, the customer may apply the thermal interface material to adhere the heatsink 130 to the semiconductor package 110. Thereafter, as needed, if the customer needs to remove the heatsink 130 from the semiconductor package 110, the support tab 720 can be rotated relative to the body or collet 710 using, for example, a screwdriver, to manipulate the TIM breaker 700 to separate the heatsink 130 from the semiconductor package 110.

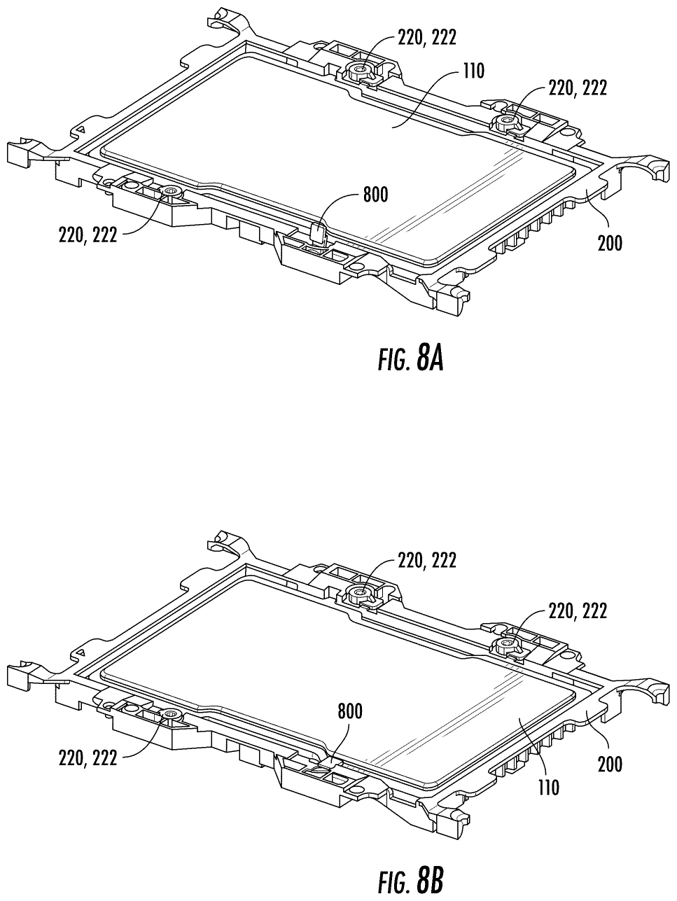

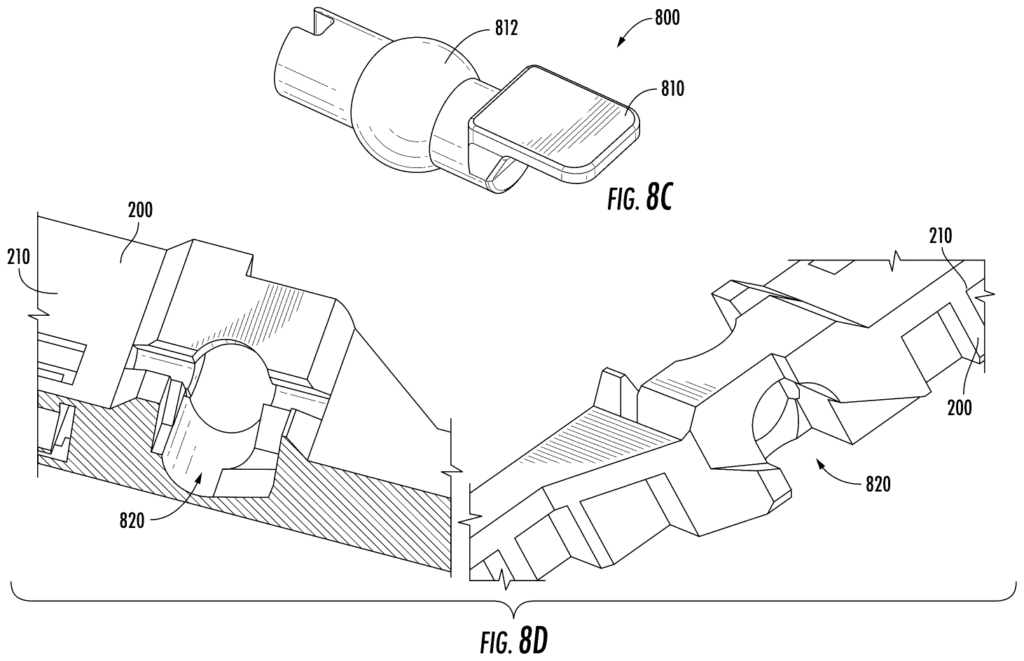

FIGS. 8A-8D illustrate a third embodiment of a TIM breaker 800 in accordance with one or more features of the present disclosure. FIG. 8A illustrates the TIM breaker 800 coupled to a semiconductor package carrier such as, for example, semiconductor package carrier 200, 300, 400, 500 (illustrated as semiconductor package carrier 200). The TIM breaker 800 illustrated in a first or opened position. FIG. 8B illustrates the TIM breaker 800 in a second or closed position. FIG. 8C illustrates a perspective view of the TIM breaker 800. FIG. 8D illustrate various perspective views of an opening formed in the semiconductor package carrier 200 to receive the TIM breaker 800. As illustrated, the TIM breaker 800 may be arranged as a ball-joint mechanism including a rotatable or ball joint support tab 810. In use, one or more TIM breakers 800 may be used in place of, or in addition to, one or more the locking structures.

As illustrated, in some embodiments, the TIM breaker 800 includes a ball joint support tab 810 rotatably positioned within an opening 820 formed in the carrier body 210 of the semiconductor package carrier 200. For example as best illustrated in FIG. 8D, the carrier body 210 of the semiconductor package carrier 200 may include an opening 820 formed therein for receiving a portion of the ball joint support tab 810. In use, the cylindrical ball-joint portion 812 enables the ball joint support tab 810 to move between a first or opened position (FIG. 8A) and a second or closed position (FIG. 8B). For example, as illustrated, the ball joint support tab 810 may pivot between a substantially vertical position (FIG. 8A) in the first or opened position to a substantially horizontal position (FIG. 8B) in the second or closed position. Thus arranged, the ball joint support tab 810 may move through a range of positions including, for example, a first or opened position and a second or closed position. In the first or opened position, the ball joint support tab 810 may be positioned so that the ball joint support tab 810 enables the semiconductor package 110 to be at least partially received within the carrier body 210 of the semiconductor package carrier 200 (e.g., the ball joint support tab 810 is vertically positioned to enable the semiconductor package 110 to be inserted into the carrier body 210 of the semiconductor package carrier 200). Thereafter, with the semiconductor package 110 inserted into the semiconductor package carrier 200, movement of the ball joint support tab 810 from the first or opened position to the second or closed position causes a portion of the ball joint support tab 810 to be positioned above the top surface of the semiconductor package 110, and eventually between the top surface of the semiconductor package 110 and the bottom surface of the heatsink 130. Movement of the ball joint support tab 810 to the second or closed position causes at least a portion of the ball joint support tab 810 to extend partially perpendicular to the periphery 214 and/or opening and across at least a portion of the semiconductor package 110 to hold the semiconductor package 110 within the semiconductor package carrier 200 thereby preventing the semiconductor package 110 from disengaging from the semiconductor package carrier 200. As such, the ball joint support tab 810 facilitates securement of the semiconductor package 110 to the semiconductor package carrier 200 similar to one or more of the locking structures previously described. Thus arranged, the TIM breaker 800 acts as a locking or retention clip. Subsequently, if the heatsink 130 needs to be decoupled from the semiconductor package 110, the ball joint support tab 810 may be rotated about a second axis relative to the carrier body 210 of the semiconductor package carrier 200. Rotation of the ball joint support tab 810 causes the end of the ball joint support tab 810 to contact and/or pry the heatsink 130 from the semiconductor package 110 to facilitate disengagement of the heatsink 130 from the semiconductor package 110.

As such, in use, TIM breaker 800 allows for two degrees of rotation. The ball joint support tab 810 can be vertically rotated between first and second positions (e.g., opened and closed positions) to facilitate insertion and/or securement of the semiconductor package 110 within the semiconductor package carrier 200. Thereafter, if needed, the ball joint support tab 810 can be rotated relative to the carrier body 210 of the semiconductor package carrier 200 via, for example, an external tool such as a screwdriver, to separate the heatsink 130 from the semiconductor package 110.

In one embodiment of use, the semiconductor package carriers 200 may be received with the TIM breaker 800 in the first or opened position. Alternatively, the TIM breaker 800 may be moved to the first or opened position. Next, a semiconductor package 110 may be inserted into the semiconductor package carrier 200. In preferred embodiments, the semiconductor package 110 may be inserted into the semiconductor package carrier 200 within the manufacturer's facilitates using automated equipment. With the semiconductor package 110 properly positioned within the semiconductor package carrier 200, each of the locking structures and/or TIM breakers 800 may be moved to the second or closed position so that the ball joint support tab 810 partially resides above the top surface of the semiconductor package 110 to secure the position of the semiconductor package 110 within the semiconductor package carrier 200. This may be done either manually or via automated equipment. Next, the shipping trays including the carrier-to-package sub-assembly may be shipped to customers where, in some embodiments, the customer may apply the thermal interface material to adhere the heatsink 130 to the semiconductor package 110. Thereafter, as needed, if the customer needs to remove the heatsink 130 from the semiconductor package 110, the ball joint support tab 810 can be rotated using, for example, a screwdriver, to manipulate the TIM breaker 800 to separate the heatsink 130 from the semiconductor package 110.

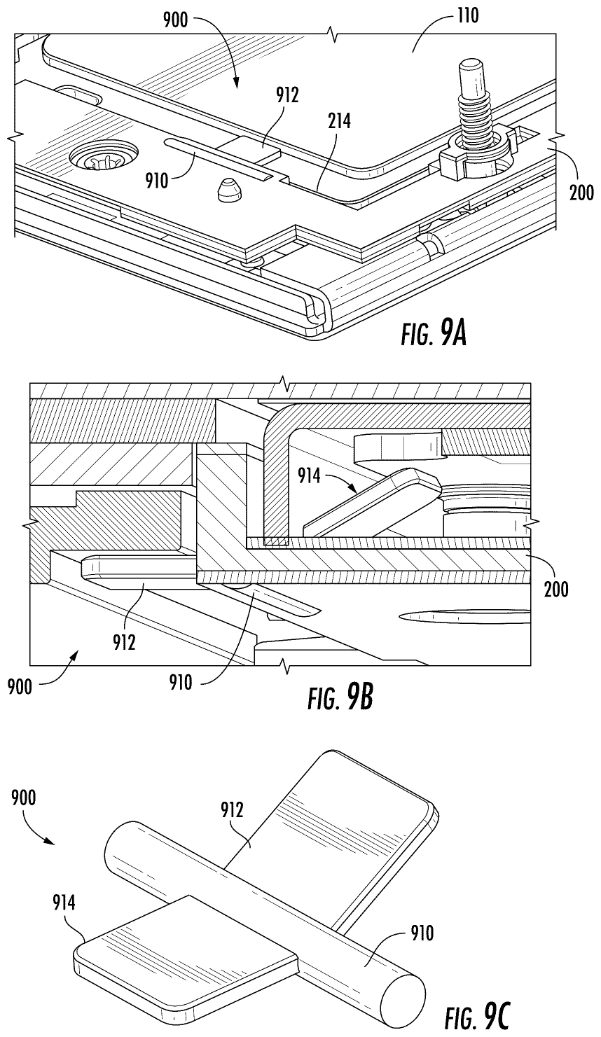

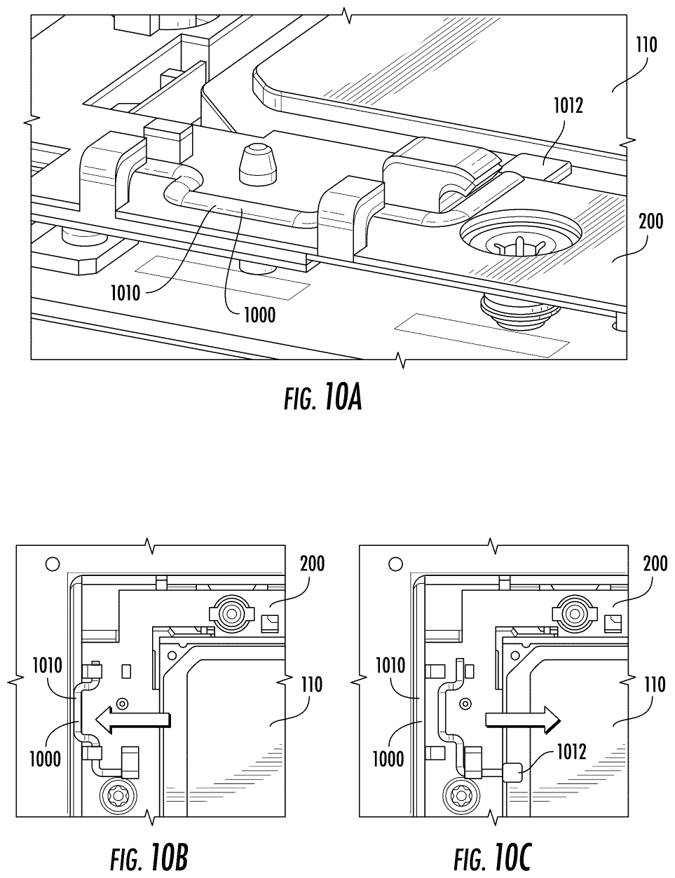

FIGS. 9A-9C illustrate a fourth embodiment of a TIM breaker 900 in accordance with one or more features of the present disclosure. FIG. 9A illustrates the TIM breaker 900 coupled to a semiconductor package carrier such as, for example, semiconductor package carrier 200, 300, 400, 500 (illustrated as semiconductor package carrier 200). The TIM breaker 900 illustrated in a second or closed position. FIG. 9B illustrates a cross-sectional view of the TIM breaker 900 positioned within the semiconductor package carrier 200. FIG. 9C illustrates a perspective view of the TIM breaker 900. As illustrated, the TIM breaker 900 may be arranged as a lever including a cylindrical support member 910 and first and second arms or tabs 912, 914. In use, one or more TIM breakers 900 may be used in place of, or in addition to, one or more the locking structures.

That is, as illustrated, in some embodiments, the TIM breaker 900 includes a support member 910 rotatably or pivotably coupled to the carrier body 210 of the semiconductor package carrier 200. For example, the support member 910 may be arranged as a cylindrical rod. In addition, the TIM breaker 900 may further including first and second arms, tabs, paddles, etc. 912, 914 extending from either direction of the support member 910. The carrier body 210 of the semiconductor package carrier 200 may include an elongated slot formed therein for receiving the support member 910. In use, the support member 910 may be pivotably or rotatably coupled to the carrier body 210 of the semiconductor package carrier 200. As such, the TIM breaker 900 may be arranged as a lever that rotates in a single axis. In use, by applying a force to one of the first and second arms 912, 914, the TIM breaker 900 may move between first and second positions. In the first position, the TIM breaker 900 may be positioned so that the first arm 912 is positioned to enable the semiconductor package 110 to be at least partially received within the carrier body 210 of the semiconductor package carrier 200 (e.g., the first arm 912 may be vertically positioned to enable the semiconductor package 110 to be inserted into the carrier body 210 of the semiconductor package carrier 200, the first arm 912 is rotated vertically to allow the semiconductor package 110 to be inserted into the semiconductor package carrier 200). Thereafter, with the semiconductor package 110 inserted into the semiconductor package carrier 200, application of a force onto the TIM breaker 900 causes the support member 910 to pivot or rotate from the first position to the second position causing the first arm 912 to be positioned above the top surface of the semiconductor package 110, and eventually between the top surface of the semiconductor package 110 and the bottom surface of the heatsink 130. With reference to FIG. 9A, movement of the TIM breaker 900 to the second or closed position causes at least a portion of the first arm 912 to extend partially perpendicular to the periphery 214 and/or opening and across at least a portion of the semiconductor package 110 to hold the semiconductor package 110 within the semiconductor package carrier 200 thereby preventing the semiconductor package 110 from disengaging from the semiconductor package carrier 200. As such, the TIM breaker 900 facilitates securement of the semiconductor package 110 to the semiconductor package carrier 200 similar to one or more of the locking structures previously described. Thus arranged, the TIM breaker 900 acts as a locking or retention clip. Subsequently, if the heatsink 130 needs to be decoupled from the semiconductor package 110, the application of a force onto the second arm 914 causes the first arm 912 to pivot or rotate about the support member 910 (e.g., similar to a see-saw) causing the first arm 912 to contact and/or pry the heatsink 130 from the semiconductor package 110 to facilitate disengagement of the heatsink 130 from the semiconductor package 110. In use, in some embodiments, the carrier body 210 of the semiconductor package carrier 200 may include an opening to facilitate insertion of an external tool such as, for example, a screwdriver, to access and apply a force onto the second arm 914 of the TIM breaker 900.

In one embodiment of use, the semiconductor package carriers 200 may be received with the TIM breaker 900 in the first or opened position. Alternatively, the TIM breaker 900 may be moved to the first or opened position. Next, a semiconductor package 110 may be inserted into the semiconductor package carrier 200. In preferred embodiments, the semiconductor package 110 may be inserted into the semiconductor package carrier 200 within the manufacturer's facilitates using automated equipment. With the semiconductor package 110 properly positioned within the semiconductor package carrier 200, each of the locking structures and/or TIM breakers 900 may be moved to the second or closed position so that the first arm 912 partially resides above the top surface of the semiconductor package 110 to secure the position of the semiconductor package 110 within the semiconductor package carrier 200. This may be done either manually or via automated equipment. Next, the shipping trays including the carrier-to-package sub-assembly may be shipped to customers where, in some embodiments, the customer may apply the thermal interface material to adhere the heatsink 130 to the semiconductor package 110. Thereafter, as needed, if the customer needs to remove the heatsink 130 from the semiconductor package 110, a force may be applied to the second arm 914 causing the first arm 912 to pivot to separate the heatsink 130 from the semiconductor package 110.

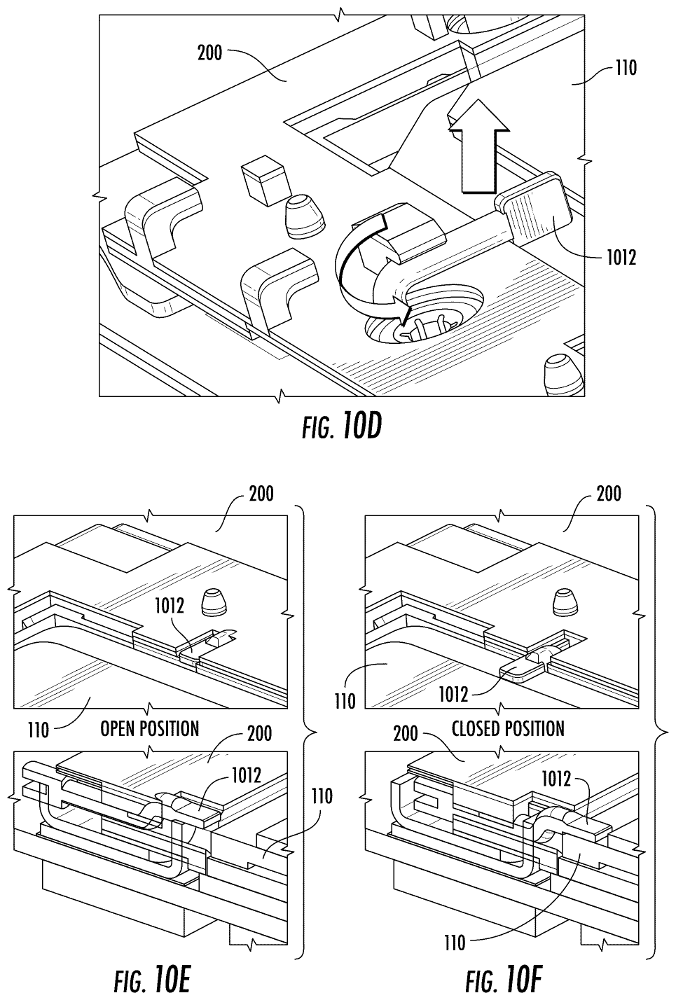

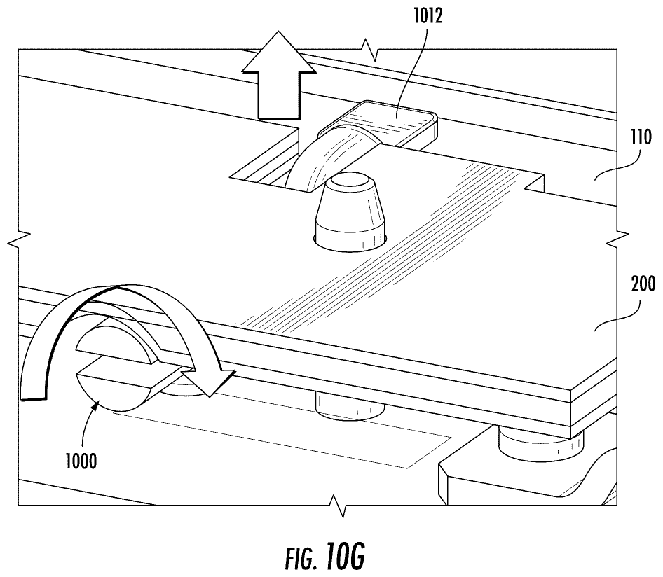

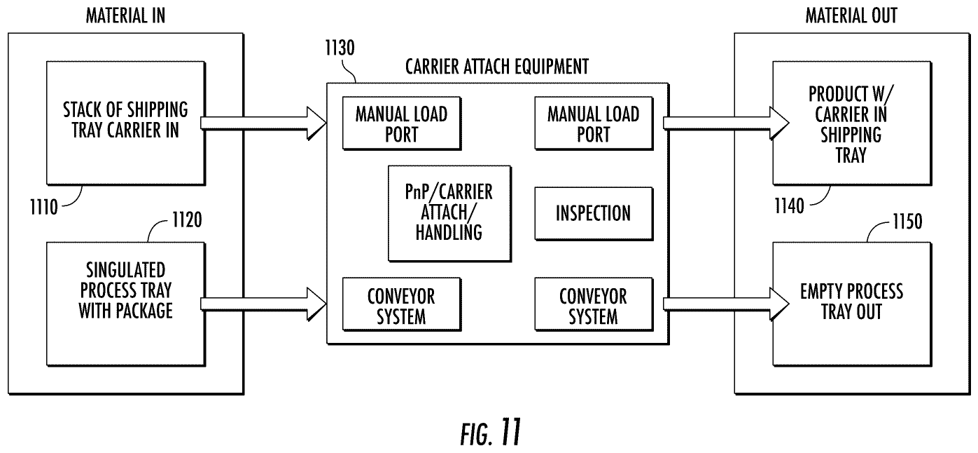

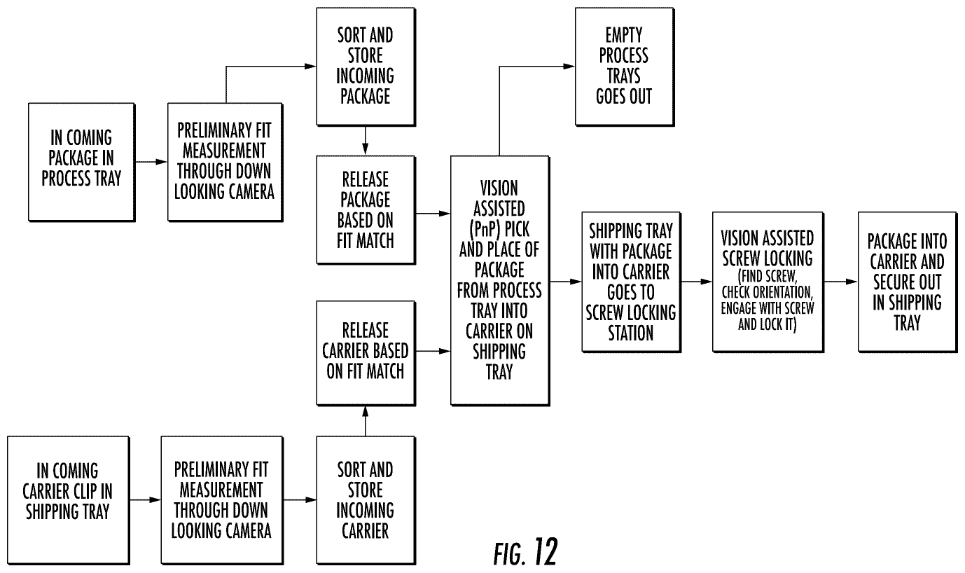

FIGS. 10A-10G illustrate a fifth embodiment of a TIM breaker 1000 in accordance with one or more features of the present disclosure. FIG. 10A illustrates a perspective view of the TIM breaker 1000 coupled to a semiconductor package carrier such as, for example, semiconductor package carrier 200, 300, 400, 500 (illustrated as semiconductor package carrier 200). The TIM breaker 1000 illustrated in a second or closed position. FIG. 10B illustrates a top view of the TIM breaker 1000 positioned within the semiconductor package carrier 200, the TIM breaker 1000 illustrated in a first or opened position. FIG. 10C illustrates a top view of the TIM breaker 1000 positioned within the semiconductor package carrier 200, the TIM breaker 1000 illustrated in the second or closed position. FIG. 10D illustrates a perspective view of the TIM breaker 1000 positioned within the semiconductor package carrier 200, the TIM breaker 1000 illustrated in a third position or configuration. FIG. 10E illustrates various views of the TIM breaker 1000 in the first or opened position. FIG. 10F illustrates various views of the TIM breaker 1000 in the second or closed position. FIG. 10G illustrates a perspective view of the TIM breaker 1000 being manipulated to the third position of configuration. As illustrated, the TIM breaker 1000 may be arranged as a lever or arm 1010 moveable (e.g., slidable) between first and second positions (e.g., opened and closed positions), and rotatable to a third position to facilitate removal of the heatsink. In use, one or more TIM breakers 1000 may be used in place of, or in addition to, one or more the locking structures.

As illustrated, in some embodiments, the TIM breaker 1000 may be arranged as a lever or arm 1010 moveably coupled to the carrier body 210 of the semiconductor package carrier 200. For example, the TIM breaker 1000 moves between first and second positions (e.g., opened and closed positions). In the first or opened position, the TIM breaker 1000 may be positioned so that an end, a tab, or a paddle 1012 is positioned to enable the semiconductor package 110 to be at least partially received within the carrier body 210 of the semiconductor package carrier 200 (e.g., the TIM breaker 1000 is moved or positioned to enable the semiconductor package 110 to be inserted into the carrier body 210 of the semiconductor package carrier 200 to allow the semiconductor package 110 to be inserted into the semiconductor package carrier 200) (as best illustrated in FIGS. 10B and 10E). Thereafter, with the semiconductor package 110 inserted into the semiconductor package carrier 200, the TIM breaker 1000 may be moved or slide to the second or closed position, wherein a portion (e.g., an end or a tab or paddle 1012) of the lever or arm 1010 (e.g., TIM breaker 1000) is positioned above the top surface of the semiconductor package 110 (as best illustrated in FIGS. 10A, 10C, and 10F). Movement of the TIM breaker 1000 to the second or closed position causes at least a portion of the TIM breaker 1000 such as, for example, an end or a tab or paddle 1012 formed thereon, to extend partially perpendicular to the periphery 214 and/or opening and across at least a portion of the semiconductor package 110 to hold the semiconductor package 110 within the semiconductor package carrier 200 thereby preventing the semiconductor package 110 from disengaging from the semiconductor package carrier 200. As such, the TIM breaker 1000 facilitates securement of the semiconductor package 110 to the semiconductor package carrier 200 similar to one or more of the locking structures previously described. Thus arranged, the TIM breaker 1000 acts as a locking or retention clip. Subsequently, with reference to FIGS. 10D and 10G, if the heatsink 130 needs to be decoupled from the semiconductor package 110, the TIM breaker 1000 can be rotated causing the portion, end, paddle, etc. 1012 to contact and/or pry the heatsink 130 from the semiconductor package 110 to facilitate disengagement of the heatsink 130 from the semiconductor package 110. In use, in some embodiments, the TIM breaker 1000 may be arranged to receive an external tool such as, for example, a screwdriver to facilitate rotation of the TIM breaker 1000.

In one embodiment of use, the semiconductor package carriers 200 may be received with the TIM breaker 1000 in the first or opened position. Alternatively, the TIM breaker 1000 may be moved to the first or closed position. Next, a semiconductor package 110 may be inserted into the semiconductor package carrier 200. In preferred embodiments, the semiconductor package 110 may be inserted into the semiconductor package carrier 200 within the manufacturer's facilitates using automated equipment. With the semiconductor package 110 properly positioned within the semiconductor package carrier 200, each of the locking structures and/or TIM breakers 1000 may be moved to the second or closed position so that a portion of the TIM breaker 1000 resides above the top surface of the semiconductor package 110 to secure the position of the semiconductor package 110 within the semiconductor package carrier 200. This may be done either manually or via automated equipment. Next, the shipping trays including the carrier-to-package sub-assembly may be shipped to customers where, in some embodiments, the customer may apply the thermal interface material to adhere the heatsink 130 to the semiconductor package 110. Thereafter, as needed, if the customer needs to remove the heatsink 130 from the semiconductor package 110, the TIM breaker 1000 can be rotated to separate the heatsink 130 from the semiconductor package 110.

With reference to FIG. 11, an embodiment of a process flow diagram for automating the carrier-to-package sub-assembly in accordance with one or more features of the present disclosure is illustrated. As schematically shown, in some embodiments, at Box 1110, stocks of shipping trays including semiconductor package carriers such as, for example, semiconductor package carriers 200, 300, 400, 500, are received. At Box 1120, stocks of process trays including semiconductor packages 110 are received. At Box 1130, automated equipment is used to load the semiconductor package 110 into the semiconductor package carrier 200, 300, 400, 500. In some embodiments, as illustrated, visual inspection, either manual or automated, is completed. At Box 1140, shipping trays of carrier-to-package sub-assemblies are outputted while empty process trays are outputted at Box 1150. In use, the shipping trays of carrier-to-package sub-assemblies can be delivered to the customers while the empty process trays can be discarded, recycled, reused, etc.

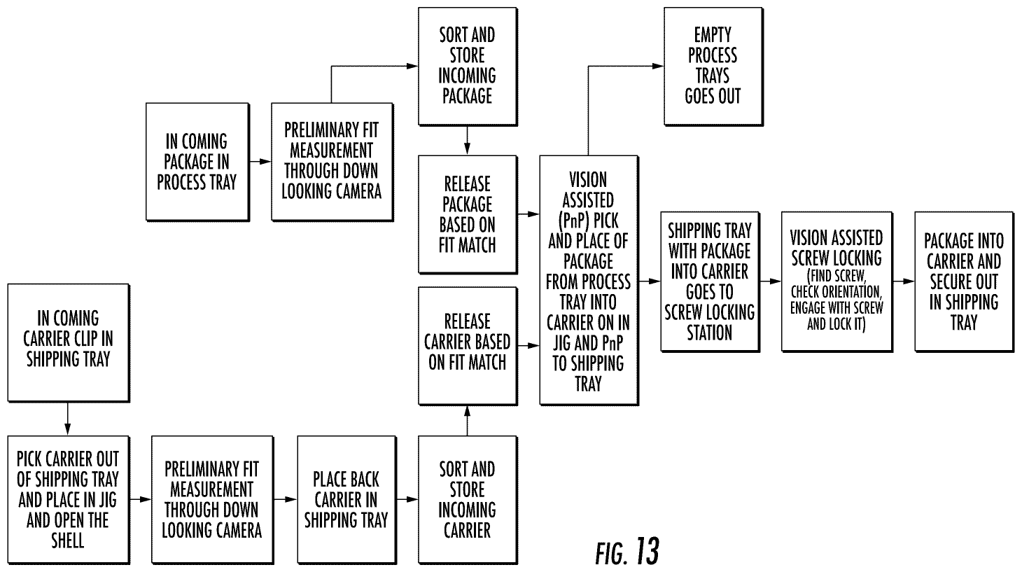

With reference to FIG. 12, an embodiment of a process flow diagram for automating the carrier-to-package sub-assembly using locking structures 220 arranged as rotatable clips 222 in accordance with one or more features of the present disclosure is illustrated. As schematically shown, in some embodiments, the semiconductor packages 110 are received within process trays. Similarly, the semiconductor package carriers 200 are received in shipping trays. In some embodiments, each of the components (e.g., semiconductor packages 110 and semiconductor package carriers 200) may be visually inspected to ensure, for example, proper sizing, using, for example, cameras. The automated machinery may record the size of each semiconductor package 110 and semiconductor package carrier 200 to identify the correct match (e.g., to ensure that the semiconductor package 110 fits inside the corresponding semiconductor package carrier 200). Next, matched components may be released for assembly. Pick head equipment may be used to insert the semiconductor package 110 into the semiconductor package carrier 200 (e.g., automated equipment may be used to grab one semiconductor package 110 and insert it into a corresponding semiconductor package carrier 200 in the proper orientation). For example, the pick head equipment may be equipped with load cells and down looking cameras. In use, the pick head equipment can be configured to identify and select the desired semiconductor package 110. Next, the pick head equipment positions the semiconductor package 110 relative to the semiconductor package carriers 200. At this point, the empty process trays used to provide the semiconductor packages 110 can be released downstream. The shipping tray including the carrier-to-package sub-assembly can move to the next location where the locking structures 220 (e.g., rotatable clips 222) can be moved from the first or opened position to the second or closed position to secure the semiconductor package 110 within the semiconductor package carrier 200. Location of the locking structures 220 (e.g., rotatable clips 222) can be identified using cameras. This process can be repeated, as necessary. Finally, a shipping tray with package-to-carrier sub-assemblies is outputted and ready for delivery.

With reference to FIG. 13, an embodiment of a process flow diagram for automating the carrier-to-package sub-assembly using a carrier body 310 including first and second hingeably coupled body portions 316, 318 in accordance with one or more features of the present disclosure is illustrated. As schematically shown, in some embodiments, the semiconductor packages 110 are received within process trays. Similarly, the semiconductor package carriers 300 are received in shipping trays. In some embodiments, the semiconductor package carriers 300 are moved to a jig for moving or opening the second body portion 318 relative to the first body portion 316. Next, each of the components (e.g., semiconductor packages 110 and semiconductor package carriers 300) may be visually inspected to ensure, for example, proper sizing, using, for example, cameras. The automated machinery may record the size of each semiconductor package 110 and semiconductor package carrier 300 to identify the correct match (e.g., to ensure that the semiconductor package 110 fits inside the corresponding semiconductor package carrier 300). With the preliminary fitting complete, the semiconductor package carriers 300 may be moved from the jig back to the shipping tray. Next, matched components may be released for assembly. Once again, in some embodiments, the semiconductor package carriers 300 may be moved from the shipping tray to a jig, where the second body portion 318 is moved or opened relative to the first body portion 316. Subsequently, a pick head equipment may be used to insert the semiconductor package 110 into the semiconductor package carrier 300 (e.g., automated equipment may be used to grab one semiconductor package 110 and insert it into a corresponding semiconductor package carrier 300 in the proper orientation). With the semiconductor package 110 inserted into the opened semiconductor package carrier 300, the second body portion 318 can be moved or closed relative to the first body portion 316 encasing the semiconductor package 110 within the semiconductor package carrier 300. Next, the carrier-to-package sub-assembly can be moved back to the shipping trays. This process can be repeated, as necessary. Finally, a shipping tray with package-to-carrier sub-assemblies is outputted and ready for delivery.

The various elements of the devices as previously described with reference to the figures include various hardware elements, software elements, or a combination of both. Examples of hardware elements include devices, logic devices, components, processors, microprocessors, circuits, processors, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), memory units, logic gates, registers, semiconductor device, chips, microchips, chip sets, and so forth. Examples of software elements include software components, programs, applications, computer programs, application programs, system programs, software development programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. However, determining whether an embodiment is implemented using hardware elements and/or software elements varies in accordance with any number of factors, such as desired computational rate, power levels, heat tolerances, processing cycle budget, input data rates, output data rates, memory resources, data bus speeds and other design or performance constraints, as desired for a given implementation.

One or more aspects of at least one embodiment are implemented by representative instructions stored on a machine-readable medium which represents various logic within the processor, which when read by a machine causes the machine to fabricate logic to perform the techniques described herein. Such representations, known as “intellectual property (IP) cores” are stored on a tangible, machine readable medium and supplied to various customers or manufacturing facilities to load into the fabrication machines that make the logic or processor. Some embodiments are implemented, for example, using a machine-readable medium or article which may store an instruction or a set of instructions that, when executed by a machine, causes the machine to perform a method and/or operations in accordance with the embodiments. Such a machine includes, for example, any suitable processing platform, computing platform, computing device, processing device, computing system, processing system, processing devices, computer, processor, or the like, and is implemented using any suitable combination of hardware and/or software. The machine-readable medium or article includes, for example, any suitable type of memory unit, memory device, memory article, memory medium, storage device, storage article, storage medium and/or storage unit, for example, memory, removable or non-removable media, erasable or non-erasable media, writeable or re-writeable media, digital or analog media, hard disk, floppy disk, Compact Disk Read Only Memory (CD-ROM), Compact Disk Recordable (CD-R), Compact Disk Rewriteable (CD-RW), optical disk, magnetic media, magneto-optical media, removable memory cards or disks, various types of Digital Versatile Disk (DVD), a tape, a cassette, or the like. The instructions include any suitable type of code, such as source code, compiled code, interpreted code, executable code, static code, dynamic code, encrypted code, and the like, implemented using any suitable high-level, low-level, object-oriented, visual, compiled and/or interpreted programming language.

As utilized herein, terms “component,” “system,” “interface,” and the like are intended to refer to a computer-related entity, hardware, software (e.g., in execution), and/or firmware. For example, a component is a processor (e.g., a microprocessor, a controller, or other processing device), a process running on a processor, a controller, an object, an executable, a program, a storage device, a computer, a tablet PC and/or a user equipment (e.g., mobile phone, etc.) with a processing device. By way of illustration, an application running on a server and the server is also a component. One or more components reside within a process, and a component is localized on one computer and/or distributed between two or more computers. A set of elements or a set of other components are described herein, in which the term “set” can be interpreted as “one or more.”

Further, these components execute from various computer readable storage media having various data structures stored thereon such as with a module, for example. The components communicate via local and/or remote processes such as in accordance with a signal having one or more data packets (e.g., data from one component interacting with another component in a local system, distributed system, and/or across a network, such as, the Internet, a local area network, a wide area network, or similar network with other systems via the signal).

As another example, a component is an apparatus with specific functionality provided by mechanical parts operated by electric or electronic circuitry, in which the electric or electronic circuitry is operated by a software application or a firmware application executed by one or more processors. The one or more processors are internal or external to the apparatus and execute at least a part of the software or firmware application. As yet another example, a component is an apparatus that provides specific functionality through electronic components without mechanical parts; the electronic components include one or more processors therein to execute software and/or firmware that confer(s), at least in part, the functionality of the electronic components.

Use of the word exemplary is intended to present concepts in a concrete fashion. As used in this application, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form. Furthermore, to the extent that the terms “including,” “includes,” “having,” “has,” “with,” or variants thereof are used in either the detailed description or the claims, such terms are intended to be inclusive in a manner similar to the term “comprising.” Additionally, in situations wherein one or more numbered items are discussed (e.g., a “first X,” a “second X,” etc.), in general the one or more numbered items may be distinct or they may be the same, although in some situations the context may indicate that they are distinct or that they are the same.

As used herein, the term “circuitry” may refer to, be part of, or include a circuit, an integrated circuit (IC), a monolithic IC, a discrete circuit, a hybrid integrated circuit (HIC), an Application Specific Integrated Circuit (ASIC), an electronic circuit, a logic circuit, a microcircuit, a hybrid circuit, a microchip, a chip, a chiplet, a chipset, a multi-chip module (MCM), a semiconductor die, a system on a chip (SoC), a processor (shared, dedicated, or group), a processor circuit, a processing circuit, or associated memory (shared, dedicated, or group) operably coupled to the circuitry that execute one or more software or firmware programs, a combinational logic circuit, or other suitable hardware components that provide the described functionality. In some embodiments, the circuitry is implemented in, or functions associated with the circuitry are implemented by, one or more software or firmware modules. In some embodiments, circuitry includes logic, at least partially operable in hardware. It is noted that hardware, firmware and/or software elements may be collectively or individually referred to herein as “logic” or “circuit.”

Some embodiments are described using the expression “one embodiment” or “an embodiment” along with their derivatives. These terms mean that a particular feature, structure, or characteristic described in connection with the embodiment is included in at least one embodiment. The appearances of the phrase “in one embodiment” in various places in the specification are not necessarily all referring to the same embodiment. Moreover, unless otherwise noted the features described above are recognized to be usable together in any combination. Thus, any features discussed separately can be employed in combination with each other unless it is noted that the features are incompatible with each other.

Some embodiments are presented in terms of program procedures executed on a computer or network of computers. A procedure is here, and generally, conceived to be a self-consistent sequence of operations leading to a desired result. These operations are those requiring physical manipulations of physical quantities. Usually, though not necessarily, these quantities take the form of electrical, magnetic or optical signals capable of being stored, transferred, combined, compared, and otherwise manipulated. It proves convenient at times, principally for reasons of common usage, to refer to these signals as bits, values, elements, symbols, characters, terms, numbers, or the like. It should be noted, however, that all of these and similar terms are to be associated with the appropriate physical quantities and are merely convenient labels applied to those quantities.

Further, the manipulations performed are often referred to in terms, such as adding or comparing, which are commonly associated with mental operations performed by a human operator. No such capability of a human operator is necessary, or desirable in most cases, in any of the operations described herein, which form part of one or more embodiments. Rather, the operations are machine operations. Useful machines for performing operations of various embodiments include general purpose digital computers or similar devices.

Some embodiments are described using the expression “coupled” and “connected” along with their derivatives. These terms are not necessarily intended as synonyms for each other. For example, some embodiments are described using the terms “connected” and/or “coupled” to indicate that two or more elements are in direct physical or electrical contact with each other. The term “coupled,” however, also means that two or more elements are not in direct contact with each other, but yet still co-operate or interact with each other.

Various embodiments also relate to apparatus or systems for performing these operations. This apparatus is specially constructed for the required purpose or it comprises a general-purpose computer as selectively activated or reconfigured by a computer program stored in the computer. The procedures presented herein are not inherently related to a particular computer or other apparatus. Various general-purpose machines are used with programs written in accordance with the teachings herein, or it proves convenient to construct more specialized apparatus to perform the required method steps. The required structure for a variety of these machines are apparent from the description given.

It is emphasized that the Abstract of the Disclosure is provided to allow a reader to quickly ascertain the nature of the technical disclosure. It is submitted with the understanding that it will not be used to interpret or limit the scope or meaning of the claims. In addition, the following claims are hereby incorporated into the Detailed Description, with each claim standing on its own as a separate embodiment. In the appended claims, the terms “including” and “in which” are used as the plain-English equivalents of the respective terms “comprising” and “wherein,” respectively. Moreover, the terms “first,” “second,” “third,” and so forth, are used merely as labels, and are not intended to impose numerical requirements on their objects.

The following examples pertain to further embodiments, from which numerous permutations and configurations will be apparent.

Example 1. An apparatus, comprising: a semiconductor package carrier comprising a carrier body including a plurality of support structures arranged to support a portion of a semiconductor package; the semiconductor package carrier further comprising a locking structure moveable between a first position and a second position, wherein the first position allows the support structures to receive the semiconductor package and the second position secures the semiconductor package to the carrier body.

Example 2. The apparatus of example 1, wherein semiconductor package is arranged to be vertically inserted into the carrier body when the locking structure is in the first position.

Example 3. The apparatus of example 1, wherein the locking structure includes a plurality of clips rotatably coupled to the carrier body, each of the plurality of clips including a support tab arranged to secure the semiconductor package within the carrier body when in the second position.

Example 4. The apparatus of example 1, wherein the carrier body includes a first body portion and a second body portion, the locking structure arranged as one or more hinges pivotably coupling the first and second body portions; wherein with the semiconductor package inserted into the first body portion, the second body portion is pivotably moved relative to the first body portion to secure the second body portion to the first body portion to secure the semiconductor package within the carrier body.

Example 5. The apparatus of example 4, wherein the one or more hinges are positioned along a first side of the carrier body, the first and second body portions further including interconnecting projections and recesses along a second side to secure the second body portion to the first body portion.

Example 6. The apparatus of example 1, wherein the carrier body includes a first body portion and a second body portion, the locking structure arranged as a plurality of interconnecting projections and recesses; wherein with the semiconductor package inserted into the first body portion, the second body portion is coupled to the first body portion to secure the second body portion to the first body portion to secure the semiconductor package within the carrier body.

Example 7. The apparatus of example 1, wherein the locking structure includes a plurality of levers moveably coupled to the carrier body, each of the plurality of levers including a support tab arranged to secure the semiconductor package within the carrier body when in the second position.

Example 8. The apparatus of example 7, wherein the plurality of levers are positioned along first and second surfaces of the carrier body; and wherein, with the semiconductor package received with the carrier body, the plurality of levers are moved to the second position.

Example 9. The apparatus of example 1, further comprising a thermal interface material (“TIM”) breaker arranged to facilitate disengagement of a heat sink from the semiconductor package.

Example 10. The apparatus of example 9, wherein the TIM breaker is moveable between a first position and a second position, wherein the first position allows the semiconductor package to be received within the carrier body; and with the semiconductor package inserted into the carrier body, movement of the TIM breaker from the first position to the second position secures the semiconductor package within the semiconductor package carrier.

Example 11. The apparatus of example 10, wherein the TIM breaker comprises a rotatable clip including an inclined surface such that with the heatsink coupled to the semiconductor package, rotation of the rotatable clip to a third position causes the inclined surface to interact with the heatsink to facilitate disengagement of the heatsink from the semiconductor package.

Example 12. The apparatus of example 10, wherein the TIM breaker comprises a rotatable clip including a support tab such that with the heatsink coupled to the semiconductor package, rotation of the support tab causes the support tab to interact with the heatsink to facilitate disengagement of the heatsink from the semiconductor package.

Example 13. The apparatus of example 10, wherein the TIM breaker comprises a ball joint including a support tab such that with the heatsink coupled to the semiconductor package, rotation of the support tab causes the support tab to interact with the heatsink to facilitate disengagement of the heatsink from the semiconductor package.

Example 14. The apparatus of example 10, wherein the TIM breaker comprises a pivot pin with first and second tabs extending therefrom such that with the heatsink coupled to the semiconductor package, contacting the second tab causes the first tab to interact with the heatsink to facilitate disengagement of the heatsink from the semiconductor package.

Example 15. The apparatus of example 10, wherein the TIM breaker comprises a lever, wherein the lever is slidably moveable from the first position to the second position, and wherein when the lever is in the second position and with the heatsink coupled to the semiconductor package, rotation of the lever causes the lever to interact with the heatsink to facilitate disengagement of the heatsink from the semiconductor package.

Example 16. A Package-Heatsink Module (PHM) comprising: a semiconductor package; and a semiconductor package carrier including: a carrier body including a plurality of support structures arranged to support a portion of the semiconductor package; and a locking structure moveable between a first position and a second position, wherein the first position allows the support structures to receive the semiconductor package and the second position secures the semiconductor package to the carrier body.

Example 17. The PHM of example 16, wherein semiconductor package is arranged to be vertically inserted into the semiconductor package carrier when the locking structure is in the first position.

Example 18. The PHM of example 16, wherein the locking structure includes a plurality of clips rotatably coupled to the carrier body, each of the plurality of clips including a support tab arranged to secure the semiconductor package within the semiconductor package carrier when in the second position.

Example 19. The PHM of example 16, wherein the carrier body includes a first body portion and a second body portion, the locking structure arranged as one or more hinges pivotably coupling the first and second body portions; wherein with the semiconductor package inserted into the first body portion, the second body portion is pivotably moved relative to the first body portion to secure the second body portion to the first body portion to secure the semiconductor package within the carrier body.

Example 20. The PHM of example 19, wherein the one or more hinges are positioned along a first side of the carrier body, the first and second body portions further including interconnecting projections and recesses along a second side to secure the second body portion to the first body portion.

Example 21. The PHM of example 16, wherein the carrier body includes a first body portion and a second body portion, the locking structure arranged as a plurality of interconnecting projections and recesses; wherein with the semiconductor package inserted into the first body portion, the second body portion is coupled to the first body portion to secure the second body portion to the first body portion to secure the semiconductor package within the carrier body.

Example 22. The PHM of example 16, wherein the locking structure includes a plurality of levers moveably coupled to the carrier body, each of the plurality of levers including a support tab arranged to secure the semiconductor package within the carrier body when in the second position.

Example 23. The PHM of example 22, wherein the plurality of levers are positioned along first and second surfaces of the carrier body; and wherein, with the semiconductor package received with the carrier body, the plurality of levers are moved to the second position.

Example 24. The PHM of example 16, further comprising a thermal interface material (“TIM”) breaker arranged to facilitate disengagement of a heat sink from the semiconductor package.

Example 25. The PHM of example 24, wherein the TIM breaker is moveable between a first position and a second position, wherein the first position allows the semiconductor package to be received within the carrier body; and with the semiconductor package inserted into the carrier body, movement of the TIM breaker from the first position to the second position secures the semiconductor package to the carrier body.

Example 26. A method comprising: selecting a semiconductor package; selecting a semiconductor package carrier comprising a carrier body; inserting the semiconductor package at least partially into the carrier body of the semiconductor package carrier; and moving a locking structure associated with the semiconductor package carrier from a first position to a second position to secure the semiconductor package within the semiconductor package carrier.

Example 27. The method of example 26, further comprising: attached a heatsink to a top surface of the semiconductor package; and moving the locking structure to disengage the heatsink from the top surface of the semiconductor package.

Example 28. An apparatus, comprising: a semiconductor package carrier comprising a carrier body including a means for supporting a portion of a semiconductor package therein; the semiconductor package carrier further comprising a means for securing the semiconductor package within the semiconductor package carrier.

Example 29. The apparatus of example 28, wherein the means for securing the semiconductor package includes a locking structure moveable between a first position and a second position, wherein the first position allows the support structures to receive the semiconductor package and the second position secures the semiconductor package to the carrier body.

Example 30. The apparatus of example 28, further comprising a means for disengaging a heatsink from the semiconductor package.

Example 31. The apparatus of example 30, wherein the means for disengaging the heatsink from the semiconductor package includes a TIM breaker moveable between first, second, and third positions, wherein the first position allows the semiconductor package to be received within the carrier body; the second position secures the semiconductor package within the semiconductor package carrier; and the third position applies a force to facilitate disengagement of the heatsink from the semiconductor package.

What is claimed is:

1. An apparatus, comprising:
a semiconductor package carrier comprising a carrier body including a plurality of support structures arranged to support a portion of a semiconductor package; and
the semiconductor package carrier further comprising a locking structure moveable between a first position and a second position, wherein the first position allows the support structures to receive the semiconductor package and the second position secures the semiconductor package to the carrier body.

2. The apparatus of claim 1, wherein the locking structure includes a plurality of clips rotatably coupled to the carrier body, each of the plurality of clips including a support tab arranged to secure the semiconductor package within the carrier body when in the second position.

3. The apparatus of claim 1, wherein the carrier body includes a first body portion and a second body portion, the locking structure arranged as one or more hinges pivotably coupling the first and second body portions;
wherein with the semiconductor package inserted into the first body portion, the second body portion is pivotably moved relative to the first body portion to secure the second body portion to the first body portion to secure the semiconductor package within the carrier body.

4. The apparatus of claim 3, wherein the one or more hinges are positioned along a first side of the carrier body, the first and second body portions further including interconnecting projections and recesses along a second side to secure the second body portion to the first body portion.

5. The apparatus of claim 1, wherein the carrier body includes a first body portion and a second body portion, the locking structure arranged as a plurality of interconnecting projections and recesses;
wherein with the semiconductor package inserted into the first body portion, the second body portion is coupled to the first body portion to secure the second body portion to the first body portion to secure the semiconductor package within the carrier body.

6. The apparatus of claim 1, wherein the locking structure includes a plurality of levers moveably coupled to the carrier body, each of the plurality of levers including a support tab arranged to secure the semiconductor package within the carrier body when in the second position.

7. The apparatus of claim 6, wherein the plurality of levers are positioned along first and second surfaces of the carrier body; and
wherein, with the semiconductor package received with the carrier body, the plurality of levers are moved to the second position.

8. The apparatus of claim 1, further comprising a thermal interface material (“TIM”) breaker arranged to facilitate disengagement of a heat sink from the semiconductor package.

9. The apparatus of claim 8, wherein the TIM breaker is moveable between a first position and a second position, wherein the first position allows the semiconductor package to be received within the carrier body; and
with the semiconductor package inserted into the carrier body, movement of the TIM breaker from the first position to the second position secures the semiconductor package within the semiconductor package carrier.

10. The apparatus of claim 9, wherein the TIM breaker comprises a rotatable clip including an inclined surface such that with the heatsink coupled to the semiconductor package, rotation of the rotatable clip to a third position causes the inclined surface to interact with the heatsink to facilitate disengagement of the heatsink from the semiconductor package.

11. The apparatus of claim 9, wherein the TIM breaker comprises a rotatable clip including a support tab such that with the heatsink coupled to the semiconductor package, rotation of the support tab causes the support tab to interact with the heatsink to facilitate disengagement of the heatsink from the semiconductor package.

12. The apparatus of claim 9, wherein the TIM breaker comprises a ball joint including a support tab such that with the heatsink coupled to the semiconductor package, rotation of the support tab causes the support tab to interact with the heatsink to facilitate disengagement of the heatsink from the semiconductor package.

13. The apparatus of claim 9, wherein the TIM breaker comprises a pivot pin with first and second tabs extending therefrom such that with the heatsink coupled to the semiconductor package, contacting the second tab causes the first tab to interact with the heatsink to facilitate disengagement of the heatsink from the semiconductor package.

14. The apparatus of claim 9, wherein the TIM breaker comprises a lever, wherein the lever is slidably moveable from the first position to the second position, and wherein when the lever is in the second position and with the heatsink coupled to the semiconductor package, rotation of the lever causes the lever to interact with the heatsink to facilitate disengagement of the heatsink from the semiconductor package.

15. A Package-Heatsink Module (PHM) comprising:
a semiconductor package; and
a semiconductor package carrier including:
a carrier body including a plurality of support structures arranged to support a portion of the semiconductor package; and
a locking structure moveable between a first position and a second position, wherein the first position allows the support structures to receive the semiconductor package and the second position secures the semiconductor package to the carrier body.

16. The PHM of claim 15, wherein the locking structure includes a plurality of clips rotatably coupled to the carrier body, each of the plurality of clips including a support tab arranged to secure the semiconductor package within the semiconductor package carrier when in the second position.

17. The PHM of claim 15, wherein the locking structure includes a plurality of levers moveably coupled to the carrier body, each of the plurality of levers including a support tab arranged to secure the semiconductor package within the carrier body when in the second position;
wherein the plurality of levers are positioned along first and second surfaces of the carrier body; and
wherein, with the semiconductor package received with the carrier body, the plurality of levers are moved to the second position.

18. The PHM of claim 15, further comprising a thermal interface material (“TIM”) breaker arranged to facilitate disengagement of a heat sink from the semiconductor package;
wherein the TIM breaker is moveable between a first position and a second position, wherein the first position allows the semiconductor package to be received within the carrier body; and with the semiconductor package inserted into the carrier body, movement of the TIM breaker from the first position to the second position secures the semiconductor package to the carrier body.

19. A method comprising:
selecting a semiconductor package;
selecting a semiconductor package carrier comprising a carrier body;
inserting the semiconductor package at least partially into the carrier body of the semiconductor package carrier; and
moving a locking structure associated with the semiconductor package carrier from a first position to a second position to secure the semiconductor package within the semiconductor package carrier.

20. The method of claim 19, further comprising:
attached a heatsink to a top surface of the semiconductor package; and
moving the locking structure to disengage the heatsink from the top surface of the semiconductor package.
